(19) United States
(12) Patent Application Publication
(10) Pub. No.: US 2022/0115438 A1
(43) Pub. Date: Apr. 14, 2022

(54) DIFFERENTIAL MAGNETOELECTRIC SPIN ORBIT LOGIC

(71) Applicant: Intel Corporation, Santa Clara, CA (US)

(72) Inventors: Hai Li, Portland, OR (US); Dmitri Nikonov, Beaverton, OR (US); Chia-Ching Lin, Portland, OR (US); Tanay Gosavi, Portland, OR (US); Ian Young, Portland, OR (US)

(73) Assignee: Intel Corporation, Santa Clara, CA (US)

(21) Appl. No.: 17/070,808

(22) Filed: Oct. 14, 2020

(51) Int. Cl. H01L 27/22; H01F 10/32

(52) U.S. Cl. CPC H01L 27/22; H01L 43/04; H01F 10/325; H01F 10/329

(57) ABSTRACT

A differential magnetoelectric spin-orbit (MESO) logic device is provided where two ports are used to connect the spin orbital module of the MESO device and a ferroelectric capacitor. In some examples, an insulating layer is added to decouple current paths.

### BACKGROUND

Spintronics is the study of intrinsic spin of the electron and its associated magnetic moment in solid-state devices. Spintronic logic are integrated circuit devices that use a physical variable of magnetization or spin as a computation variable. Such variables can be non-volatile (e.g., preserving a computation state when the power to an integrated circuit is switched off). Non-volatile logic can improve the power and computational efficiency by allowing architects to put a processor to un-powered sleep states more often and therefore reduce energy consumption. Existing spintronic logic generally suffer from high energy and relatively long switching times.

For example, large write current (e.g., greater than 100 μA/bit) and voltage (e.g., greater than 0.7 V) are needed to switch a magnet (i.e., to write data to the magnet) in Magnetic Tunnel Junctions (MTJs). Existing Magnetic Random-Access Memory (MRAM) based on MTJs also suffer from high write error rates (WERs) or low speed switching. For example, to achieve lower WERs, switching time is slowed down which degrades the performance of the MRAM. MTJ based MRAMs also suffer from reliability issues due to tunneling current in the spin filtering tunneling dielectric of the MTJs e.g., magnesium oxide (MgO). An arithmetic logic unit (ALU) is a useful block for any logic function, where a full adder (FA) is a common logic block. Conventional 1-bit Complementary Metal Oxide Semiconductor (CMOS) adder may require eight to twenty-eight transistors. Scaling the adder design in area and power is a challenge. The same challenge exists in current spintronic logic.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A illustrates a magnetization response to an applied magnetic field for a ferromagnet.

FIG. 1B illustrates a magnetization response to an applied magnetic field for a paramagnet.

FIG. 1C illustrates a magnetization response to an applied voltage field for a paramagnet (or ferromagnet) connected to a magnetoelectric layer.

FIG. 2A illustrates a unidirectional magnetoelectric spin orbit (MESO) logic.

FIG. 2B illustrates a spin orbit material stack at the input of an interconnect.

FIG. 2C illustrates a magnetoelectric material stack at the output of an interconnect.

FIG. 3A illustrates an equivalent circuit model for a first section (e.g., input section) of the unidirectional MESO logic of FIG. 2A.

FIG. 3B illustrates an equivalent circuit model for a second section (e.g., output section) of the unidirectional MESO logic of FIG. 2A.

FIGS. 4A-B illustrate a ferroelectric Landau Khalatnikov (LK) model and corresponding plot showing two ferroelectric states.

FIG. 5 illustrates a differential MESO logic, in accordance with some embodiments.

FIG. 6 illustrates a circuitry model of the differential MESO logic, in accordance with some embodiments.

FIG. 7 illustrates a model of cascaded differential MESO logic devices, in accordance with some embodiments.

FIG. 8 illustrates a set of plots showing simulation or timing diagram of the model of FIG. 7, in accordance with some embodiments.

FIG. 9 illustrates a majority gate of 5 inputs using the differential MESO logic devices, in accordance with some embodiments.

FIGS. 10A-B illustrate a set of plots showing simulation of the majority gate of FIG. 9, in accordance with some embodiments.

FIG. 11 illustrates a smart device or a computer system or a SoC (System-on-Chip) with apparatus for dynamic reallocation of SoC power, in accordance with some embodiments.

### DETAILED DESCRIPTION

Complementary Metal Oxide Semiconductor (CMOS) majority/minority gate-based logic design results in increased gate count due to the logic inefficiency using CMOS for majority/minority function. Using novel spin or quantum devices (e.g. quantum cellular automata (QCA), tunneling phase logic (TPL), and single electron tunneling (SET) has shown gate reduction compared to conventional CMOS circuits due to the retaliating of majority/minority function within a few devices. The nano-magnet based 1-bit adder uses 2 magnetic tunneling junction-nanowire (MTJ-nanowire) devices for minority gate operation but it requires additional CMOS based circuits with sixteen transistors for two sense amplifiers with additional two reference MTJs for pre-charge. The nano-magnet based 1-bit adder also uses an inverter for the carry-out to the 5-input majority gate, besides additional peripheral circuits and MTJs for the current input generation to the adder. While QCA is designed with less transistor assistance, but it requires five cells for one 3-input majority gate and over 80 devices for complete function and additional transistors for clocking signal generation.

Technology scaling is an important factor of success for the semiconductor industry, where beyond CMOS (Complementary Metal Oxide Semiconductor) technology is being considered to enable future technology scaling below 5 nm technology node. One beyond CMOS technology employs Magnetoelectric (ME) effect. The ME effect has the ability to manipulate the magnetization (and the associated spin of electrons in the material) by an applied electric field. Since an estimated energy dissipation per unit area per magnet switching event through the ME effect is an order of magnitude smaller than with spin-transfer torque (STT) effect, ME materials have the capability for next-generation memory and logic applications.

Magnetoelectric Spin Orbit (MESO) Logic devices/gates when cascaded have a resistive leakage path, which induces interference to MESO with the off state. A typical MESO logic device requires two transistors per MESO stage to cut off part of the leakage paths. Further majority gate output voltage for typical single-ended MESO logic is inconsistent and depends on the input MESO states.

Various embodiments describe a differential MESO logic device to overcome challenges faced by existing single-ended MESO device. The MESO logic is a combination of various physical phenomena for spin-to-charge and charge-to-spin conversion, where the MESO logic comprises an input magnet and stack of layers for spin-to-charge conversion. Spin-to-charge conversion is achieved via one or more layers with the inverse Rashba-Edelstein effect (or spin Hall effect) wherein a spin current injected from the input magnet produces a charge current. The sign of the charge current is determined by the polarization direction of the injected spin and thus magnetization of magnet. In some embodiments, charge-to-spin conversion is achieved via magnetoelectric effect in which the charge current produces a voltage on a capacitor, comprising a layer with magnetoelectric effect, leading to switching magnetization of an output magnet. In some embodiments, magnetic response of a magnet is according to an applied exchange bias from the magnetoelectric effect. In some embodiments, two ports are used to connect the spin orbital module of the MESO device and the ferroelectric capacitor. In some embodiments, an insulating layer is added to decouple current paths.

In some embodiments, an apparatus is provided which comprises a first cell comprising a first magnetoelectric material, a first spin orbit material, and a first magnet, wherein the first magnet is between the first spin orbit material and the first magnetoelectric material. In some embodiments, the first magnet comprises a stack comprising an insulating magnet between two magnets. In some embodiments, the apparatus comprises a second cell comprising a second magnetoelectric material, a second spin orbit material, and a second magnet, wherein the second magnet is between the second spin orbit material and the second magnetoelectric material. In some embodiments, the apparatus a first conductor coupled to the first spin orbit material and a first terminal of the second magnetoelectric material; and a second conductor coupled to the first spin orbit material and a second terminal of the second magnetoelectric material.

In some embodiments, the first cell comprises: a first structure comprising the first magnetoelectric material; a second structure comprising the first magnet, wherein the second structure is adjacent to the first structure; and a third structure comprising the first spin orbit material, wherein the third structure is adjacent to the second structure, wherein the second structure is between the first structure and third structure. In some embodiments, the second cell comprises: a fourth structure comprising the second magnetoelectric material a fifth structure comprising the second magnet, wherein the fifth structure is adjacent to the fourth structure; and a sixth structure comprising the second spin orbit material, wherein the sixth structure is adjacent to the fifth structure, wherein the fifth structure is between the fourth structure and sixth structure. In some embodiments, the first magnet is a first ferromagnet, and wherein the second structure comprises: a second ferroelectric magnet; and an insulative ferroelectric magnet between the first ferroelectric magnet and the second ferroelectric magnet.

In some embodiments, the third or sixth structures include one or more of: β-Ta, β-W, W, Pt, Cu doped with Iridium, Cu doped with Bismuth, or Cu doped an element of 3d, 4d, 5d, 4f, or 5f of periodic table groups. In some embodiments, apparatus of claim 3, wherein the first or fourth structures include BFO, SRO, and STO. In some embodiments, the apparatus comprises: a first transistor controllable by a first phase of a clock, wherein the first transistor is coupled to the third structure; and a second transistor controllable by a second phase of the clock, wherein the second transistor is coupled to sixth structure. In some embodiments, the first phase and second phase are different and do not overlap. In some embodiments, the first or second magnetoelectric material include one or more of: BiFeO₃, LuFeO₂, LuFe₂O₄, or La doped BiFeO₃, or wherein the multiferroic material includes one of: Bi, Fe, O, Lu, or La. In some embodiments, the first or second magnets include a paramagnet or a ferromagnet, or wherein the first and second magnets comprises a material which includes one or more of: Pt, Pd, W, Ce, Al, Li, Mg, Na, Cr, O, Co, Dy, Er, Eu, Gd, Fe, Nd, K, Pr, Sm, Tb, Tm, or V. In some embodiments, the first or second magnets include one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, Ru. While various embodiments here illustrate a magnetoelectric capacitor, the magnetoelectric capacitor can be replaced with a ferroelectric capacitor.

There are many technical effects of various embodiments. For example, high speed operation of the logic (e.g., 100 picoseconds (ps)) is achieved via the use of magnetoelectric switching operating on semi-insulating nanomagnets. In some examples, switching energy is reduced (e.g., 1-10 attojoules (aJ)) because the current needs to be “on” for a shorter time (e.g., approximately 3 ps) in order to charge the capacitor. In some examples, in contrast to the spin current, here charge current does not attenuate when it flows through an interconnect. Compared to typical spiking neural networks, the learning circuits for oscillator neural networks using differential MESO logic device(s) cut resistive leakage path, avoid interference for intermediate stages (when MESO logic devices are cascaded), provide symmetric signal and stabilize bias conditions, enable single-clock pulse switching instead of two-clock overlapping fashion, avoid using footer transistor, and allow for more coherent fabrication steps. Moreover, MESO is a low voltage device which can operate at 100 mV with aJ class switching energy, offering promising path for future technology scaling and energy efficiency benefits. Other technical effects will be evident from the various figures and embodiments.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “adjacent” here generally refers to a position of a thing being next to (e.g., immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, magnetic signal, or data/clock signal. The meaning of “a,” “an,” and “the” include plural references. The meaning of “in” includes “in” and “on.”

The term “analog signal” is any continuous signal for which the time varying feature (variable) of the signal is a representation of some other time varying quantity, i.e., analogous to another time varying signal.

The term “digital signal” is a physical signal that is a representation of a sequence of discrete values (a quantified discrete-time signal), for example of an arbitrary bit stream, or of a digitized (sampled and analog-to-digital converted) analog signal.

The term “scaling” generally refers to converting a design (schematic and layout) from one process technology to another process technology and may be subsequently being reduced in layout area. In some cases, scaling also refers to upsizing a design from one process technology to another process technology and may be subsequently increasing layout area. The term “scaling” generally also refers to downsizing or upsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

It is pointed out that those elements of the figures having the same reference numbers (or names) as the elements of any other figure can operate or function in any manner similar to that described but are not limited to such.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors (BJT PNP/NPN), BiCMOS, CMOS, etc., may be used without departing from the scope of the disclosure.

Here the term “supervisor” generally refers to a power controller, or power management, unit (a “p-unit”), which monitors and manages power and performance related parameters for one or more associated power domains, either alone or in cooperation with one or more other p-units. Power/performance related parameters may include but are not limited to domain power, platform power, voltage, voltage domain current, die current, load-line, temperature, utilization, clock frequency, processing efficiency, current/future workload information, and other parameters. It may determine new power or performance parameters (limits, average operational, etc.) for the one or more domains. These parameters may then be communicated to supervisee p-units, or directly to controlled or monitored entities such as VR or clock throttle control registers, via one or more fabrics and/or interconnects. A supervisor learns of the workload (present and future) of one or more dies, power measurements of the one or more dies, and other parameters (e.g., platform level power boundaries) and determines new power limits for the one or more dies. These power limits are then communicated by supervisor p-units to the supervisee p-units via one or more fabrics and/or interconnect. In examples where a die has one p-unit, a supervisor (Svor) p-unit is also referred to as supervisor die.

Here the term “supervisee” generally refers to a power controller, or power management, unit (a “p-unit”), which monitors and manages power and performance related parameters for one or more associated power domains, either alone or in cooperation with one or more other p-units and receives instructions from a supervisor to set power and/or performance parameters (e.g., supply voltage, operating frequency, maximum current, throttling threshold, etc.) for its associated power domain. In examples where a die has one p-unit, a supervisee (Svee) p-unit may also be referred to as a supervisee die. Note that a p-unit may serve either as a Svor, a Svee, or both a Svor/Svee p-unit

Here, the term “processor core” generally refers to an independent execution unit that can run one program thread at a time in parallel with other cores. A processor core may include a dedicated power controller or power control unit (p-unit) which can be dynamically or statically configured as a supervisor or supervisee. This dedicated p-unit is also referred to as an autonomous p-unit, in some examples. In some examples, all processor cores are of the same size and functionality i.e., symmetric cores. However, processor cores can also be asymmetric. For example, some processor cores have different size and/or function than other processor cores. A processor core can be a virtual processor core or a physical processor core.

Here the term “die” generally refers to a single continuous piece of semiconductor material (e.g. silicon) where transistors or other components making up a processor core may reside. Multi-core processors may have two or more processors on a single die, but alternatively, the two or more processors may be provided on two or more respective dies. Each die has a dedicated power controller or power control unit (p-unit) power controller or power control unit (p-unit) which can be dynamically or statically configured as a supervisor or supervisee. In some examples, dies are of the same size and functionality i.e., symmetric cores. However, dies can also be asymmetric. For example, some dies have different size and/or function than other dies.

Here, the term “interconnect” refers to a communication link, or channel, between two or more points or nodes. It may comprise one or more separate conduction paths such as wires, vias, waveguides, passive components, and/or active components. It may also comprise a fabric.

Here the term “interface” generally refers to software and/or hardware used to communicate with an interconnect. An interface may include logic and I/O driver/receiver to send and receive data over the interconnect or one or more wires.

Here the term “fabric” generally refers to communication mechanism having a known set of sources, destinations, routing rules, topology and other properties. The sources and destinations may be any type of data handling functional unit such as power management units. Fabrics can be two-dimensional spanning along an x-y plane of a die and/or three-dimensional (3D) spanning along an x-y-z plane of a stack of vertical and horizontally positioned dies. A single fabric may span multiple dies. A fabric can take any topology such as mesh topology, star topology, daisy chain topology. A fabric may be part of a network-on-chip (NoC) with multiple agents. These agents can be any functional unit.

Here the term “dielet” or “chiplet” generally refers to a physically distinct semiconductor die, typically connected to an adjacent die in a way that allows the fabric across a die boundary to function like a single fabric rather than as two distinct fabrics. Thus at least some dies may be dielets. Each dielet may include one or more p-units which can be dynamically or statically configured as a supervisor, supervisee or both.

Here the term “domain” generally refers to a logical or physical perimeter that has similar properties (e.g., supply voltage, operating frequency, type of circuits or logic, and/or workload type) and/or is controlled by a particular agent. For example, a domain may be a group of logic units or function units that are controlled by a particular supervisor. A domain may also be referred to an Autonomous Perimeter (AP). A domain can be an entire system-on-chip (SoC) or part of the SoC, and is governed by a p-unit.

The term “free” or “unfixed” here with reference to a magnet refers to a magnet whose magnetization direction can change along its easy axis upon application of an external field or force (e.g., Oersted field, spin torque, etc.). Conversely, the term “fixed” or “pinned” here with reference to a magnet refers to a magnet whose magnetization direction is pinned or fixed along an axis and which may not change due to application of an external field (e.g., electrical field, Oersted field, spin torque).

Here, perpendicularly magnetized magnet (or perpendicular magnet, or magnet with perpendicular magnetic anisotropy (PMA)) refers to a magnet having a magnetization which is substantially perpendicular to a plane of the magnet or a device. For example, a magnet with a magnetization which is in a z-direction in a range of 90 (or 270) degrees+/−20 degrees relative to an x-y plane of a device.

Here, an in-plane magnet refers to a magnet that has magnetization in a direction substantially along the plane of the magnet. For example, a magnet with a magnetization which is in an x or y direction and is in a range of 0 (or 180 degrees)+/−20 degrees relative to an x-y plane of a device.

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

Here, multiple non-silicon semiconductor material layers may be stacked within a single fin structure. The multiple non-silicon semiconductor material layers may include one or more “P-type” layers that are suitable (e.g., offer higher hole mobility than silicon) for P-type transistors. The multiple non-silicon semiconductor material layers may further include one or more “N-type” layers that are suitable (e.g., offer higher electron mobility than silicon) for N-type transistors. The multiple non-silicon semiconductor material layers may further include one or more intervening layers separating the N-type from the P-type layers. The intervening layers may be at least partially sacrificial, for example to allow one or more of a gate, source, or drain to wrap completely around a channel region of one or more of the N-type and P-type transistors. The multiple non-silicon semiconductor material layers may be fabricated, at least in part, with self-aligned techniques such that a stacked CMOS device may include both a high-mobility N-type and P-type transistor with a footprint of a single finFET.

Here, the term “backend” generally refers to a section of a die which is opposite of a “frontend” and where an IC (integrated circuit) package couples to IC die bumps. For example, high level metal layers (e.g., metal layer 6 and above in a ten-metal stack die) and corresponding vias that are closer to a die package are considered part of the backend of the die. Conversely, the term “frontend” generally refers to a section of the die that includes the active region (e.g., where transistors are fabricated) and low-level metal layers and corresponding vias that are closer to the active region (e.g., metal layer 5 and below in the ten-metal stack die example).

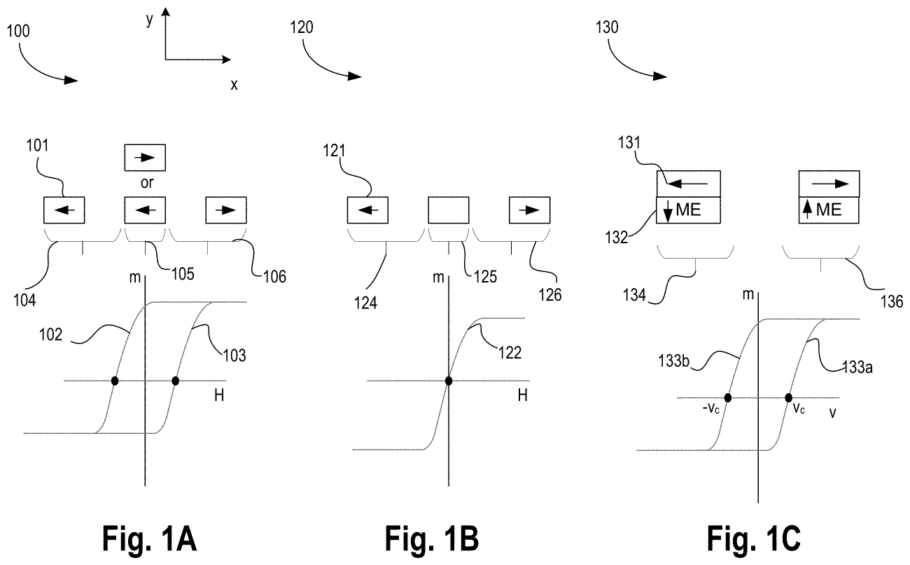

FIG. 1A illustrates a magnetization hysteresis plot 100 for ferromagnet 101. The plot shows magnetization response to applied magnetic field for ferromagnet 101. The x-axis of plot 100 is magnetic field ‘H’ while the y-axis is magnetization ‘m’. For ferromagnet (FM) 101, the relationship between ‘H’ and ‘m’ is not linear and results in a hysteresis loop as shown by curves 102 and 103. The maximum and minimum magnetic field regions of the hysteresis loop correspond to saturated magnetization configurations 104 and 106, respectively. In saturated magnetization configurations 104 and 106, FM 101 has stable magnetizations. In the zero magnetic field region 105 of the hysteresis loop, FM 101 does not have a definite value of magnetization, but rather depends on the history of applied magnetic fields. For example, the magnetization of FM 101 in configuration 105 can be either in the +x direction or the −x direction for an in-plane FM. As such, changing or switching the state of FM 101 from one magnetization direction (e.g., configuration 104) to another magnetization direction (e.g., configuration 106) is time consuming resulting in slower nanomagnets response time. It is associated with the intrinsic energy of switching proportional to the area in the graph contained between curves 102 and 103. Semi-insulating or insulating magnets also have a hysteresis curve and can be used as magnets in various embodiments.

In some embodiments, FM 101 is formed of CFGG (i.e., Cobalt (Co), Iron (Fe), Germanium (Ge), or Gallium (Ga) or a combination of them). In some embodiments, FM 101 comprises one or more of Co, Fe, Ni alloys and multilayer hetero-structures, various oxide ferromagnets, garnets, or Heusler alloys. Heusler alloys are ferromagnetic metal alloys based on a Heusler phase. Heusler phases are intermetallic with certain composition and face-centered cubic crystal structure. The ferromagnetic property of the Heusler alloys are a result of a double-exchange mechanism between neighboring magnetic ions. In some embodiments, the Heusler alloy includes one of: Cu₂MnAl, Cu₂MnIn, Cu₂MnSn, Ni₂MnAl, Ni₂MnIn, Ni₂MnSn, Ni₂MnSb, Ni₂MnGa Co₂MnAl, Co₂MnSi, Co₂MnGa, Co₂MnGe, Pd₂MnAl, Pd₂MnIn, Pd₂MnSn, Pd₂MnSb, Co₂FeSi, Co₂FeAl, Fe₂VAl, Mn₂VGa, Co₂FeGe, MnGa, or MnGaRu.

FIG. 1B illustrates magnetization plot 120 for paramagnet 121. Plot 120 shows the magnetization response to applied magnetic field for paramagnet 121. The x-axis of plot 120 is magnetic field ‘H’ while the y-axis is magnetization ‘m’. A paramagnet, as opposed to a ferromagnet, exhibits magnetization when a magnetic field is applied to it. Paramagnets generally have magnetic permeability greater or equal to one and hence are attracted to magnetic fields. Compared to plot 100, magnetic plot 120 of FIG. 1B does not exhibit hysteresis which allows for faster switching speeds and smaller switching energies between the two saturated magnetization configurations 124 and 126 of curve 122. In the middle region 125, paramagnet 121 does not have any magnetization because there is no applied magnetic field (e.g., H=0). The intrinsic energy associated with switching is absent in this case.

In some embodiments, paramagnet 121 comprises a material which includes one or more of: Platinum (Pt), Palladium (Pd), Tungsten (W), Cerium (Ce), Aluminum (Al), Lithium (Li), Magnesium (Mg), Sodium (Na), Cr₂O₃ (chromium oxide), CoO (cobalt oxide), Dysprosium (Dy), Dy₂O (dysprosium oxide), Erbium (Er), Er₂O₃ (Erbium oxide), Europium (Eu), Eu₂O₃ (Europium oxide), Gadolinium (Gd), Gadolinium oxide (Gd₂O₃), FeO and Fe₂O₃ (Iron oxide), Neodymium (Nd), Nd₂O₃ (Neodymium oxide), KO₂ (potassium superoxide), praseodymium (Pr), Samarium (Sm), Sm₂O₃ (samarium oxide), Terbium (Tb), Tb₂O₃ (Terbium oxide), Thulium (Tm), Tm₂O₃ (Thulium oxide), or V₂O₃ (Vanadium oxide). In some embodiments, paramagnet 121 comprises dopants which include one or more of: Ce, Cr, Mn, Nb, Mo, Tc, Re, Nd, Gd, Tb, Dy, Ho, Er, Tm, or Yb. In various embodiments, the magnet can be either a FM or a paramagnet.

FIG. 1C illustrates plot 130 showing magnetization response to applied voltage field for a paramagnet 131 connected to a magnetoelectric layer 132. Here, the x-axis is voltage ‘V’ applied across magnetoelectric (ME) layer 132 and y-axis is magnetization ‘m’. Ferroelectric polarization ‘P_{FE}’ is in ME layer 132 as indicated by an arrow. In this example, magnetization is driven by exchange bias exerted by a ME effect from ME layer 132. When positive voltage is applied to ME layer 132, paramagnet 131 establishes a deterministic magnetization (e.g., in the +x direction by voltage +V_{c}) as shown by configuration 136. When negative voltage is applied by ME layer 132, paramagnet (or ferromagnet) 131 establishes a deterministic magnetization (e.g., in the −x direction by voltage −V_{c}) as shown by configuration 134. Plot 130 shows that magnetization functions 133a and 133b have hysteresis. In some embodiments, by combining ME layer 132 with paramagnet 131, switching speeds of paramagnet as shown in FIG. 1B are achieved. In some embodiments, the hysteresis behavior of FM 131, as shown in FIG. 1C, is associated with the driving force of switching rather than the intrinsic resistance of the magnet to switching.

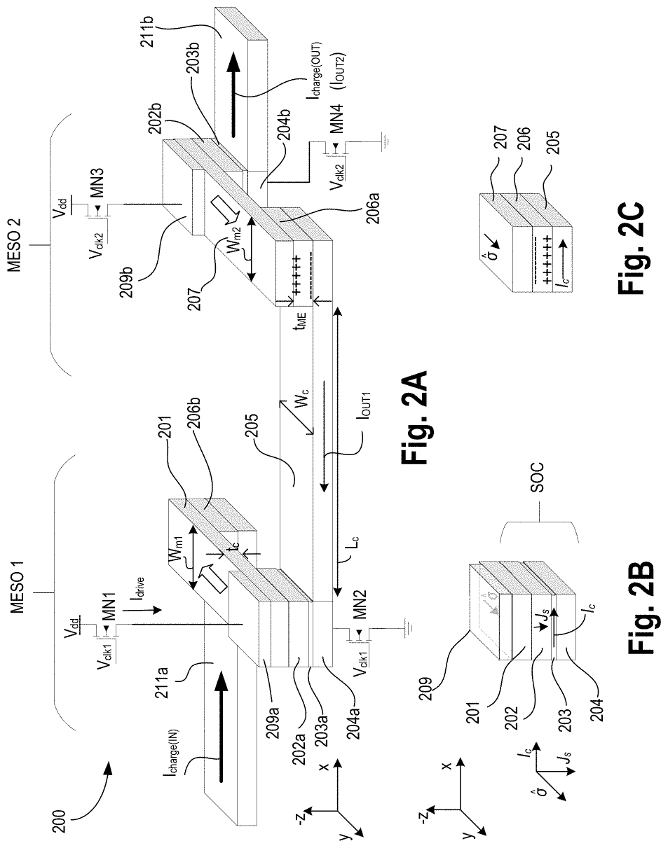

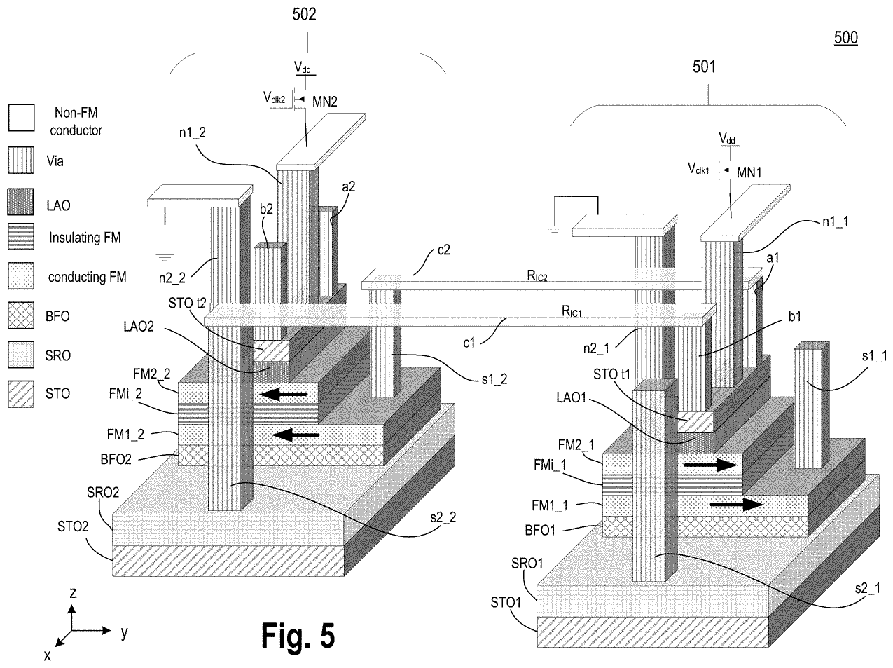

FIG. 2A illustrates a unidirectional magnetoelectric spin orbit (MESO) logic. FIG. 2B illustrates a material stack at the input of an interconnect. FIG. 2C illustrates a magnetoelectric material stack at the output of an interconnect. It is pointed out that those elements of FIGS. 2A-C having the same reference numbers (or names) as the elements of any other figure can operate or function in any manner similar to that described, but are not limited to such. In various embodiments, the materials and coupling of various structures and materials of FIGS. 2A-C are applicable to the differential MESO logic of FIG. 5.

Referring back to FIGS. 2A-C, here, MESO logic 200 comprises a first magnet 201, a stack of layers (e.g., layers 202, 203, and 204, also labeled as 202a/b, 203a/b, and 204a/b), interconnecting conductor 205 (e.g., a non-magnetic charge conductor), magnetoelectric (ME) layer 206 (206a/b), second magnet 207, first contact 209a, and second contact 209b. In this example, first and second magnets 201 and 207, respectively, have in-plane magnetic anisotropy. First magnet 201 comprises first and second portions, wherein the first portion of first magnet 201 is adjacent to the stack of layers (e.g., layers 202a, 203a, and 204a), and wherein the second portion of first magnet 201 is adjacent to a magnetoelectric (ME) material stack or layer 206b. Second magnet 207 comprises first and second portions, wherein the first portion of second magnet 207 is adjacent to the magnetoelectric material stack or layer 206a, and wherein the second portion of second magnet 207 is adjacent to stack of layers (e.g., layers 202b, 203b, and 204b).

Here, conductor 205 (or charge interconnect) is coupled to at least a portion of the stack of layers (e.g., one of layers 202a, 203a, or 204a) and ME layer 206a. For example, conductor 205 is coupled to layer 204a of the stack. The stack of layers (e.g., layers 202a/b, 203a/b, or 204a/b) is to provide an inverse Rashba-Edelstein effect (or inverse spin Hall effect). The stack of layers provides spin-to-charge conversion where a spin current Iₛ (or spin energy Jₛ is injected from first magnet 201 and charge current I_{c} is generated by the stack of layers. This charge current I_{c} is provided to conductor 205 (e.g., charge interconnect). In contrast to spin current, charge current does not attenuate in conductor 205. The direction of the charge current I_{c} depends on the direction of magnetization of first magnet 201.

The charge current I_{c} charges the capacitor around ME layer 206a and switches its polarization. ME layer 206a exerts exchange bias on second magnet layer 207, and the direction of the exchange bias determines the magnetization of second magnet 207. The same dynamics occurs by ME layer 206b which exerts exchange bias on first magnet 201 according to input charge current on conductor 211a.

In this example, the length of first magnet 201 is Lₘ, the width of conductor 205 is W_{c}, the length of conductor 205 from the interface of layer 204a to ME layer 206a is L_{c}, t_{c} is the thickness of the magnets 201 and 207, and t_{ME} is the thickness of ME layer 206a. In some embodiments, conductor 205 comprises a material including one of: Graphene, Cu, Ag, Al, or Au.

The input and output charge conductors (211a and 211b, respectively) and associated spin-to-charge and charge-to-spin converters are provided. Input charge current I_{charge(IN)} (or I_{IN}) is provided on interconnect 211a (e.g., charge interconnect made of same material as interconnect 205). Interconnect 211a is coupled to first magnet 201 via ME layer 206b. Interconnect 211a is orthogonal to first magnet 201. For example, interconnect 211a extends in the +x direction while first magnet 201 extends in the −y direction. I_{charge(IN)} is converted to corresponding magnetic polarization of 201 by ME layer 206b. The materials for ME layers 206a/b are the same as the materials of ME layer 206.

An output interconnect 211b is provided to transfer output charge current I_{charge(OUT)} to another logic or stage. Output interconnect 211b is coupled to second magnet 207 via a stack of layers that exhibit spin Hall effect and/or Rashba-Edelstein effect. For example, layers 202b, 203b, and 204b are provided as a stack to couple output interconnect 211b with second magnet 207. Material wise, layers 202b, 203b, and 204b are formed of the same material as layers 202a, 203a, and 204a, respectively.

ME layer 206a/b forms the magnetoelectric capacitor to switch the magnets 201/207. For example, conductor 205 forms one plate of the capacitor, magnet 207 forms the other plate of the capacitor, and layer 206a is the magnetic-electric oxide that provides out-of-plane exchange bias to second magnet 207. In some embodiments, layer 206a provides in-plane exchange bias to second magnet 207. The magnetoelectric oxide comprises perpendicular exchange bias due to partially compensated anti-ferromagnetism.

First magnet 201 injects a spin polarized current into the high spin-orbit coupling (SOC) material stack (e.g., layers 202a, 203a, and 204a). The spin polarization is determined by the magnetization of first magnet 201.

The stack comprises i) interface layer 203a/b with a high density 2D (two dimensional) electron gas and with high SOC formed between 202a/b and 204a/b materials such as Ag or Bi, or ii) a bulk material 204 with high Spin Hall Effect (SHE) coefficient such as Ta, W, or Pt. A spacer (or template layer) is formed between first magnet 201 and the injection stack. This spacer is a templating metal layer which provides a template for forming first magnet 201. The metal of the spacer which is directly coupled to first magnet 201 is a noble metal (e.g., Ag, Cu, or Au) doped with other elements from Group 4d and/or 5d of the Periodic Table. First magnet 201 (and by extension first semi-insulating magnet 209a) are sufficiently lattice matched to Ag (e.g., a material which is engineered to have a lattice constant close (e.g., within 3%) to that of Ag).

Here, sufficiently matched atomistic crystalline layers refer to matching of the lattice constant ‘a’ within a threshold level above which atoms exhibit dislocation which is harmful to the device (for instance, the number and character of dislocations lead to a significant (e.g., greater than 10%) probability of spin flip while an electron traverses the interface layer). For example, the threshold level is within 5% (i.e., threshold levels in the range of 0% to 5% of the relative difference of the lattice constants). As the matching improves (i.e., matching gets closer to perfect matching), spin injection efficiency from spin transfer from first magnet 201 to first ISHE/ISOC stacked layer increases. Poor matching (e.g., matching worse than 5%) implies dislocation of atoms that is harmful for the device.

Table 1 summarizes transduction mechanisms for converting magnetization to charge current and charge current to magnetization for bulk materials and interfaces.

TABLE 1
Transduction mechanisms for Spin to
Charge and Charge to Spin Conversion

| | Spin → Charge | Charge → Spin |
|---|---|---|
| Bulk | Inverse Spin Hall Effect | Magnetoelectric effect |
| Interface | Inverse Rashba-Edelstein | Magnetoelectric effect |
| | Effect | |

In this example, a transistor (e.g., n-type transistor MN1) is coupled to first contact 209a. Here, the drain terminal of transistor MN1 is coupled to a supply V_{dd}, the gate terminal of transistor MN1 is coupled to a control voltage \T_{clk1} (e.g., a switching clock signal, which switches between V_{dd} and ground), and the source terminal of transistor MN1 is coupled to first contact 209a. First contact 209a is made of any suitable conducting material used to connect the transistor to the first magnet 201. The current I_{drive} (or I_{SUPPLY}) from transistor MN1 generates spin current into the stack of layers (e.g., layers 202a, 203a, and 204a). After passing through the ferromagnetic layer, charge current becomes spin current and then spin current converts to charge after going through SoC material (e.g., layers 202a, 203a, and 204a).

In some examples, along with the n-type transistor MN1 connected to V_{dd}, an n-type transistor MN2 is provided which couples layer 203a of the stack of layers (202a, 203a, and 204a) to ground. Here, the drain terminal of transistor MN2 is coupled to layer 204a, the gate terminal of transistor MN2 is coupled to a control voltage V_{clk1} (e.g., a switching clock signal, which switches between V_{dd} and ground), and the source terminal of transistor MN2 is coupled to ground.

In some examples, n-type transistor MN3 is provided which is operable to couple power supply V_{dd} to second contact 209b. Here, the drain terminal of transistor MN3 is coupled to a supply V_{dd}, the gate terminal of transistor MN3 is coupled to a control voltage V_{clk2} (e.g., a switching clock signal, which switches between V_{dd} and ground and is of different phase than V_{clk1}), and the source terminal of transistor MN3 is coupled to second contact 209b. In some examples, second contact 209b is made of any suitable conducting material used to connect the transistor to the second magnet 207. In some examples, the current I_{drive} from transistor MN3 generates spin current into the stack of layers (e.g., layers 202b, 203b, and 204b).

In some examples, along with the n-type transistor MN4 connected to V_{dd}, an n-type transistor MN4 is provided which couples layer 204b of the stack of layers (202b, 203b, and 204b) to ground. Here, the drain terminal of transistor MN4 is coupled to layer 203b, the gate terminal of transistor MN4 is coupled to a control voltage V_{clk2}, and the source terminal of transistor MN4 is coupled to ground.

For purposes of explaining MESO logic device 200, MESO logic device can be considered to have two portions or sections. The first portion/section (or MESO input cell MESO 1) comprises components/layers from 211a to the left of conductor 205, and the second portion/section (or MESO output cell MESO 2) comprises conductor 205 to layer 211b to the right. An ideal unidirectional signal propagation scenario is as follows: an input charge current drives magnet 201 while a supply charge current is injected to the spin-orbit coupling (SOC) stack (202a, 203a, 204a). The magnet 201 switches and its directionality determine the output charge current (I_{OUT1}) direction in conductor 205. The output current loon of the first MESO section drives the second MESO section, which continues to switch the MESO of that section. In the absence of transistors MN2 and MN4, simply connecting the two MESO sections in series can cause the ferroelectric capacitor in the second section of the MESO to switch input magnet 201 of the first section, which disturbs the logic operation.

In some examples, transistors MN1 and MN2 of the first section are in series with the nanomagnet 201 and SOC stack (202a, 203a, and 204a). In some examples, transistors MN3 and MN4 of the second section are in series with the nanomagnet 207 and SOC stack (202b, 203b, and 204b). In some examples, different clock signals (V_{clk1} and V_{clk2}) are applied to the gate terminals of the transistors, where transistors connected to the same MESO section share the same clock. The polarization direction of the ferroelectric charge in the magnet stack determines the magnetic directions of the nano-magnets 201 and 207, which determines the output current direction.

In this example, in the first MESO section, I_{IN} (or I_{charge(IN)}) from input conductor 211a induces positive polarization charge on the bottom plate of the ferroelectric (FE) capacitor 206b and results in polarization of magnet 201. With a charge current I_{SUPPLY} (or I_{drive}) from layer 209a to 204a, output current I_{OUT1} is generated on conductor 205 which is inversed from the input. Current I_{OUT1} then provides input current to the next MESO section. This current induces a negative polarization charge on the bottom plate of the ferroelectric capacitor 206a of the next MESO section. This polarization charge causes magnet 207 of the second MESO section to switch which results in the output current I_{OUT2} to be in the same direction as I_{IN} (with the same I_{SUPPLY} current direction).

The following section describes the spin to charge and charge to spin dynamics. The spin-orbit mechanism responsible for spin-to-charge conversion is described by the inverse Rashba-Edelstein effect in 2D electron gases. The Hamiltonian (energy) of spin-orbit coupling electrons in a 2D electron gas is:

$${H}_{R} = {α}_{R} ( k \times \hat{z} ) \cdot {σ}^{`}$$

where α_{R} is the Rashba-Edelstein coefficient, ‘k’ is the operator of momentum of electrons, \hat{z} is a unit vector perpendicular to the 2D electron gas, and \grave{σ} is the operator of spin of electrons.

The spin polarized electrons with direction of polarization in-plane (e.g., in the xy-plane) experience an effective magnetic field dependent on the spin direction:

$$B ( {k}^{`} ) = \frac{{α}_{R}}{{μ}_{B}} ( {k}^{`} \times \hat{z} )$$

where μ_{B} is the Bohr magneton.

This results in the generation of a charge current I_{c} in interconnect 205 proportional to the spin current Iₛ (or Jₛ). The spin-orbit interaction by Ag and Bi interface layers 202 and 204 (e.g., the Inverse Rashba-Edelstein Effect (IREE)) produces a charge current I_{c} in the horizontal direction given as:

$${I}_{c} = \frac{{λ}_{IREE} {I}_{s}}{{w}_{m}}$$

where wₘ is width of the input magnet 201, and λ_{IREE} is the IREE constant (with units of length) proportional to α_{R}.

Alternatively, the Inverse Spin Hall Effect in Ta, W, or Pt layer 203a/b produces the horizontal charge current I_{c} given as:

$${I}_{c} = \frac{{Θ}_{S H E} {t}_{S H E} {I}_{s}}{2 {w}_{m}}$$

Both IREE and ISHE effects produce spin-to-charge current conversion with efficiency around 0.1 with existing materials at 10 nm (nanometers) magnet width. For scaled nanomagnets (e.g., 5 nm wide magnets) and exploratory SHE materials such as Bi₂Se₃, the spin-to-charge conversion efficiency can be between 1 and 2.5. The net conversion of the drive charge current I_{drive} to magnetization dependent charge current is given as:

$${I}_{c} = \pm \frac{{λ}_{IREE} {PI}_{s}}{{w}_{m}} for IREE and {I}_{c} = \pm \frac{{Θ}_{S H E} {t}_{SHE} {PI}_{s}}{2 {w}_{m}} for ISHE$$

where ‘P’ is the dimensionless spin polarization. For this estimate, the drive current I_{drive} and the charge current I_{c}=I_{d}=100 μA is set. As such, when estimating the resistance of the ISHE interface to be equal to R=100Ω, then the induced voltage is equal to V_{ISHE}=10 mV.

The charge current I_{c}, carried by interconnect 205, produces a voltage on the capacitor of ME layer 206a comprising magnetoelectric material dielectric (such as BiFeO₃ (BFO) or Cr₂O₃) in contact with second magnet 207 (which serves as one of the plates of the capacitor) and interconnect 205 (which serves as the other of the plates of the capacitor). In some embodiments, magnetoelectric materials are either intrinsic multiferroic or composite multiferroic structures. As the charge accumulates on the magnetoelectric capacitor of ME layer 206a, a strong magnetoelectric interaction causes the switching of magnetization in second magnet 207 (and by extension second semi-insulating magnet 209b).

For the following parameters of the magnetoelectric capacitor: thickness t_{ME}=5 nm, dielectric constant ε=500, area A=60 nm×20 nm. Then the capacitance is given as:

$$C = \frac{ɛ {ɛ}_{0} A}{{t}_{M E}} \approx 1 fF$$

Demonstrated values of the magnetoelectric coefficient is α_{ME}˜10/c, where the speed of light is c. This translates to the effective magnetic field exerted on second semi-insulating magnet 207, which is expressed as:

$${B}_{M E} = {α}_{M E} E = \frac{{α}_{M E} {V}_{ISHE}}{{t}_{M E}} ∼ 0.06 T$$

This is a strong field sufficient to switch magnetization.

The charge on the capacitor of ME layer 206a is Q=1 fF×10 mV=10 αC, and the time to fully charge it to the induced voltage is

$$t d = 10 \frac{Q}{{I}_{d}} ∼ 1 ps$$

(with the account or decreased voltage difference as the capacitor charges). If the driving voltage is V_{d}=100 mV, then the energy E_{sw} to switch is expressed as:

$${E}_{s w} ∼ 100 mV \times 100 μ A \times 1 ps ∼ 10 aJ$$

which is comparable to the switching energy of CMOS transistors. Note that the time to switch t_{sw} magnetization remains much longer than the charging time and is determined by the magnetization precession rate. The micro-magnetic simulations predict this time to be t_{sw}˜100 ps, for example.

In some embodiments, materials for first and second magnets 201 and 207 have saturated magnetization Mₛ and effective anisotropy field Hₖ. Saturated magnetization Mₛ is generally the state reached when an increase in applied external magnetic field H cannot increase the magnetization of the material. Anisotropy Hₖ generally refers material properties that are highly directionally dependent.

In some embodiments, materials for first and second magnets 201 and 207, respectively, are non-ferromagnetic elements with strong paramagnetism which have a high number of unpaired spins but are not room temperature ferromagnets. A paramagnet, as opposed to a ferromagnet, exhibits magnetization when a magnetic field is applied to it. Paramagnets generally have magnetic permeability greater or equal to one and hence are attracted to magnetic fields. In some embodiments, magnets 201 and/or 207 comprise a material which includes one or more of: Platinum (Pt), Palladium (Pd), Tungsten (W), Cerium (Ce), Aluminum (Al), Lithium (Li), Magnesium (Mg), Sodium (Na), Cr₂O₃ (chromium oxide), CoO (cobalt oxide), Dysprosium (Dy), Dy₂O (dysprosium oxide), Erbium (Er), Er₂O₃ (Erbium oxide), Europium (Eu), Eu₂O₃ (Europium oxide), Gadolinium (Gd), Gadolinium oxide (Gd₂O₃), FeO and Fe₂O₃ (Iron oxide), Neodymium (Nd), Nd₂O₃ (Neodymium oxide), KO₂ (potassium superoxide), praseodymium (Pr), Samarium (Sm), Sm₂O₃ (samarium oxide), Terbium (Tb), Tb₂O₃ (Terbium oxide), Thulium (Tm), Tm₂O₃ (Thulium oxide), or V₂O₃ (Vanadium oxide). In some embodiments, the first and second paramagnets 201 and 207 comprise dopants selected from a group which includes one or more of: Ce, Cr, Mn, Nb, Mo, Tc, Re, Nd, Gd, Tb, Dy, Ho, Er, Tm, or Yb.

In some embodiments, first and second magnets 201 and 207, respectively, are ferromagnets. In some embodiments, first and second magnets 201 and 207, respectively, comprise one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, Ru, Cu₂MnAl, Cu₂MnIn, Cu₂MnSn, Ni₂MnAl, Ni₂MnIn, Ni₂MnSn, Ni₂MnSb, Ni₂MnGa Co₂MnAl, Co₂MnSi, Co₂MnGa, Co₂MnGe, Pd₂MnAl, Pd₂MnIn, Pd₂MnSn, Pd₂MnSb, Co₂FeSi, Co₂FeAl, Fe₂VAl, Mn₂VGa, Co₂FeGe, MnGa, MnGaRu, or Mn₃X, where ‘X’ is one of Ga or Ge.

In some examples, the stack of layers providing spin orbit coupling comprises: a first layer 202a/b comprising Ag, wherein the first layer is adjacent to first magnet 201; and a second layer 204a/b comprising Bi or W, wherein second layer 204a/b is adjacent to first layer 202a/b and to a conductor (e.g., 205, 211b). In some examples, a third layer 203a/b (having material which is one or more of Ta, W, or Pt) is sandwiched between first layer 202a/b and second layer 204a/b as shown. In some examples, the stack of layers comprises a material which includes one of: β-Ta, β-W, W, Pt, Cu doped with Iridium, Cu doped with Bismuth, or Cu doped an element of 3d, 4d, 5d, 4f, or 5f of periodic table groups.

ME materials may be divided into three categories. The first category of materials provide polarization and anti-ferromagnetization. These materials include Bismuth ferrite (BFO), Lithium Iron Oxide (LFO) super lattice. The second category of materials also provide polarization and anti-ferromagnetization, but at low temperatures. These materials include TbMnO₃ and similar multiferroic materials. The third category of materials are magnetoelectric para-electrics. These magnetoelectric para-electrics materials lack polarization, but provide anti-ferromagnetization. The magnetoelectric para-electrics materials include chromia (Cr₂O₃).

In some embodiments, ME layer 206a/b comprises one of: dielectric, para-electric, or ferro-electric material. In some embodiments, ME layer 206a/b is formed of a material which includes one of: Cr₂O₃ and multiferroic material. In some embodiments, ME layer 206 comprises Cr and O. In some embodiments, the multiferroic material comprises BFO (e.g., BiFeO₃), LFO (LuFeO₂, LuFe₂O₄), or La doped BiFeO₃. In some embodiments, the multiferroic material includes one of: Bi, Fe, O, Lu, or La.

In some embodiments, first contact 209a is replaced with a first semi-insulating magnet 209a, and second contact 209b is replaced with a second semi-insulating magnet 209b. In some embodiments, first semi-insulating magnet 209a is adjacent to first magnet 201 and is also coupled to a transistor (e.g., n-type transistor MN1). As such, first semi-insulating magnet 209a functions as a displacement capacitor between the transistor MN1 and the first magnet 201. Here the term “semi-insulating magnet” generally refers to a material that has magnetic properties but has higher resistivity compared to normal ferromagnets. For example, semi-insulating or insulating magnets may not be conductive for charge current, but exhibit magnetic properties. The semi-insulating magnet or insulating magnet may have a Spinel crystal structure, can be hexagonal (e.g., Fe₂O₃), or they can belong to any of the crystal classes. In some embodiments, materials for semi-insulating or insulating magnets include one of: Fe₂O₃, Co₂O₃, Co₂FeO₄, or Ni₂FeO₄. In some embodiments, elements for semi-insulating or insulating magnets include one or more of: Fe, O, Co or Ni. The direction of the charge current I_{c} also depends on the direction of magnetization of first semi-insulating magnet 209a.

In some embodiments, first semi-insulating magnet 209a and second semi-insulating magnet 209b form displacement capacitors. The nature of the displacement capacitor may be set by the leakage and the dielectric constants of the semi-insulating magnets 209a/b. In some embodiments, first semi-insulating magnet 209a and second semi-insulating magnet 209b form dielectric capacitors, where a bound charge is generated at the plates.

In some embodiments, first and second semi-insulating magnets 209a and 209b, respectively, comprise a material which includes one or more of: Co, Fe, No, or O. In some embodiments, the first and second semi-insulating magnets 209a and 209b, respectively, comprise a material which includes one or more of: Co₂O₃, Fe₂O₃, Co₂FeO₄, or Ni₂FeO₄. In some embodiments, first and second semi-insulating magnets 209a and 209b have Spinel crystal structure. In some embodiments, magnets 209a and 209b have non-insulating properties. For example, magnets 209a and 209b can be paramagnets or ferromagnets.

In some embodiments, the magnetization of first semi-insulating magnet 209a is determined by the magnetization of first magnet 201. For example, when first magnet 201 has magnetizations pointing in −y direction, then first semi-insulating magnet 209a has magnetization pointing in the −y direction. In some embodiments, the magnetization of second semi-insulating magnet 209b is determined by the magnetization of second magnet 207. For example, when second magnet 207 has magnetizations pointing in −y direction, then second semi-insulating magnet 209b has magnetization pointing in the −y direction. In some embodiments, second semi-insulating magnet 209b is adjacent to second magnet 207 such that second magnet 207 is between second semi-insulating magnet 209b and the stack of layers providing spin orbit coupling.

While various examples are illustrated with n-type transistors MN1, MN2, MN3, and MN4, p-type transistors can be used instead and the switching gate signals can be logically inversed. In some examples, a combination of n-type and p-type transistors are used. For example, the transistors coupled to power supply Vdd are p-type transistors while the transistors coupled to ground are n-type transistors. Appropriate logic change can be made to the driving gate signals to achieve the same technical effect (e.g., unidirectionality) as achieved by the n-type transistors MN1, MN2, MN3, and MN4. In some embodiments, a combination of n-type and p-type devices (e.g., transmission gates) can be used instead of n-type transistors MN1, MN2, MN3, and MN4.

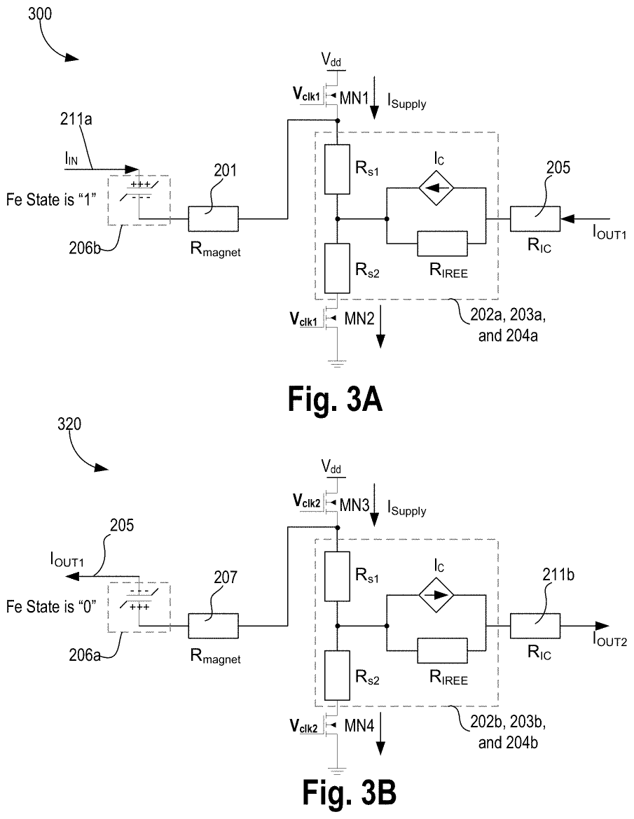

FIG. 3A illustrates an equivalent circuit model 300 for the first section (or MESO input cell) of the unidirectional MESO logic of FIG. 2A. Here R_{magnet}, Rₛ₁, Rₛ₂, R_{IREE} and R_{IC} are the modeled resistances for magnet 201, SOC stack (202a, 203a, 204a) shunt resistance, the Inverse Rashba-Edelstein Effect (IREE) resistance, and interconnect resistance of conductor 205, respectively. The IREE effect from the current in the SOC stack is modeled as a current controlled current source, of which the current direction is determined by the magnet “state” (e.g., the nano-magnet direction, which is inconsistent with the polarization charge in the ferroelectric). In some embodiments, the ferroelectric 206b is modeled as a non-linear capacitor using Landau Khalatnikov (LK) equations.

FIG. 3B illustrates an equivalent circuit model 320 for the second section (e.g., MESO output cell) of the unidirectional MESO logic of FIG. 2A. Here R_{magnet}, Rₛ₁, Rₛ₂, R_{IREE} and R_{IC} are the modeled resistances for magnet 207, SOC stack (202b, 203b, 204b) shunt resistance, the Inverse Rashba-Edelstein Effect (IREE) resistance, and interconnect resistance of conductor 211b, respectively. The IREE effect from the current in the SOC stack is modeled as a current controlled current source, of which the current direction is determined by the magnet “state” (e.g., the nano-magnet direction, which is inconsistent with the polarization charge in the ferroelectric). In some examples, the ferroelectric 206a is modeled as a non-linear capacitor using LK equations. In some examples, to enable the unidirectional signal propagation, V_{clk1} and V_{clk2} are out-of-phase and with overlap. In some examples, V_{clk1} and V_{clk2} are out-of-phase and non-overlapping. For example, V_{clk1} and V_{clk2} are out-of-phase by 180°.

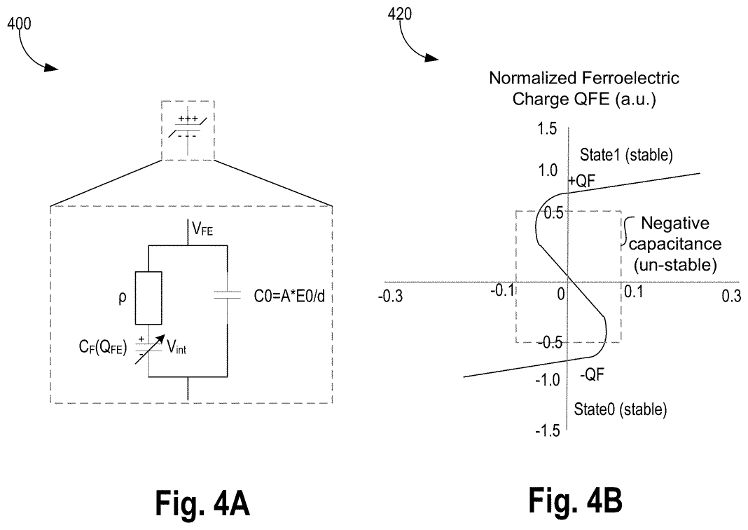

FIGS. 4A-B illustrate a ferroelectric Landau Khalatnikov (LK) model 400 and corresponding plot 420, respectively, showing two ferroelectric states. In some examples, positive polarization charge +QF corresponds to state ‘1’ of the magnet, while negative polarization charge −QF corresponds to state ‘0’ of the magnet. Here, normalized +QF(1) and −QF(−1) are used in circuit simulation to indicate the ferroelectric states.

LK model 400 illustrates a circuit that provides ferroelectric voltage V_{FE} and comprises capacitor C0 in parallel with a series coupled resistance ρ and internal capacitance C_{F}(Q_{FE}) that provides internal voltage Vᵢₙₜ. Here, ‘A’ is the area of capacitor C0, ‘d’ is the distance between the plates of capacitor C0, and E0 is the dielectric constant. Plot 420 shows the capacitance behavior of a ferroelectric capacitor (FE-Cap) when connected with a load capacitor. Here, the x-axis is the internal voltage Vᵢₙₜ in volts, while the y-axis is the charge from the ferroelectric capacitor when connected with a load capacitor. The dotted region in plot 420 represents the negative capacitance region between the coercive voltage bounds.

When a voltage source drives the FE-Cap connected with a load capacitor, the operating region of a FE-cap is biased by the load capacitance. When the FE-Cap is biased at the negative capacitance region (e.g., charge on FE-cap is positive while the voltage across the FE-cap is negative, and vice versa), the voltage across the load capacitance can be higher than the input voltage, owning to the ferroelectric polarity charge induced voltage amplification effect. On the other hand, when the FE-Cap is biased at the positive capacitance region, it operates as a regular capacitor. The negative capacitance effect has been mainly utilized for transistor gate stack enhancement (e.g., negative capacitance FETs) for low-voltage transistors. Some examples use the concept of negative capacitance to a MESO logic to enhance the switching of magnets via the magnetoelectric layer.

FIG. 5 illustrates differential MESO logic 500, in accordance with some embodiments. Differential MESO logic 500 comprises MESO cell 501 and MESO cell 502. In some embodiments, MESO cell 501 comprises a first structure comprising Strontium titanate SrTiO3 (herein STO1), a second structure comprising Strontium ruthenate SrRuO3 (herein SRO1), a third structure comprising ME material, a fourth structure comprising a first conductive ferroelectric (herein FM1_1), a fifth structure comprising a insulative ferroelectric (herein FM1_1), a sixth structure comprising a second conductive ferroelectric (herein FM2_1), a seventh structure comprising Lanthanum aluminate LaAlO3 (herein LAO1); an eight structure comprising STO (herein STO t1), conductive vias s2_1, s1_1, n1_1, n2_1, a1, and b1, and associated conductors coupled to them, respectively, and transistor MN1 coupled to via n1_1 by means of an electrode or conductor. The spin orbit stack comprises STO t1 and LAO1. However, the spin orbit stack can also comprise the SOC layers discussed with reference to FIGS. 2A-B (e.g., 202, 203, and 204).

Referring back to FIG. 5, In various embodiments, STO1 is adjacent to SRO1. In some embodiments, SRO1 is adjacent to BFO1. In some embodiments, FM1_1 is adjacent to BFO1. In some embodiments, FM1_1 is adjacent to FMi_1. In some embodiments, FMi_1 is adjacent to FM2_1. In some embodiments, LAO1 is adjacent to FM2_1. In some embodiments, LAO1 is adjacent to STO t1. Via s2_1 is coupled to SRO1. Via s1_1 is coupled to FM1_1. Via n2_1 is coupled to FM2_1. Via a1 is coupled to one end of STO t1. Via b1 is coupled to another end of STO t1. Via n1_1 is coupled to STO t1 between vias a1 and b1. Via n2_1 is coupled to ground via its respective conductor. In some embodiments, the stack of layers comprising FM1_1, FMi_1, and FM2_1 can be replaced with one layer of a ferromagnet.

In some embodiments, MESO cell 502 comprises a first structure comprising Strontium titanate SrTiO3 (herein STO2), a second structure comprising Strontium ruthenate SrRuO3 (herein SRO1), a third structure comprising ME material, a fourth structure comprising a first conductive ferroelectric (herein FM1_2), a fifth structure comprising a insulative ferroelectric (herein FMi_2), a sixth structure comprising a second conductive ferroelectric (herein FM2_2), a seventh structure comprising Lanthanum aluminate LaAlO3 (herein LAO1); an eight structure comprising STO (herein STO t2), conductive vias s2_1, s1_2, n1_2, n2_2, a2, and b2, and associated conductors coupled to them, respectively, and transistor MN2 coupled to via n1_2 by means of an electrode or conductor. The spin orbit stack comprises STO t2 and LAO2. However, the spin orbit stack can also comprise the SOC layers discussed with reference to FIGS. 2A-B (e.g., 202, 203, and 204).

Referring back to FIG. 5, in various embodiments, STO2 is adjacent to SRO2. In some embodiments, SRO2 is adjacent to BFO2. In some embodiments, FM1_2 is adjacent to BFO2. In some embodiments, FM1_2 is adjacent to FMi_2. In some embodiments, FMi_2 is adjacent to FM2_2. In some embodiments, LAO2 is adjacent to FM2_2. In some embodiments, LAO2 is adjacent to STO t2. Via s2_2 is coupled to SRO2. Via s1_2 is coupled to FM1_2. Via n2_2 is coupled to FM2_2. Via a2 is coupled to one end of STO t2. Via b2 is coupled to another end of STO t2. Via n1_2 is coupled to STO t2 between vias a2 and b2. Via n2_2 is coupled to ground via its respective conductor. In some embodiments, the stack of layers comprising FM1_2, FMi_2, and FM2_2 can be replaced with one layer of a ferromagnet.

The following thicknesses along the z-axis are provided for MESO cell 501. The same thicknesses apply for MESO cell 502. The thickness of the STO t1 along the z-axis is less than 20 nm. The thickness of the LAO1 along the z-axis is less than 20 nm. The thickness of the magnets (e.g., FM1_1, FMi_1, FM2_1) along the z-axis is less than 5 nm. The thickness of BFO1 along the z-axis is less than 5 nm. The thickness of SRO1 is less than 20 nm. The thickness of STO1 is less than 20 nm.

In various embodiments, MESO cell 501 is coupled to MESO cell 502 via conductors c1 and c2. Conductor c1 (having resistance R1c1) couples via b1 of MESO cell 501 to s2_2 of MESO cell 502. As such, the spin-orbit module of MESO 501 is coupled to one terminal of the ME or ferroelectric (FE) capacitor of MESO cell 502. In some embodiments, via a1 of MESO cell 501 is coupled to the second terminal of the ME or FE capacitor MESO cell 502 via conductor c2. As such, MESO1 501 and MESO2 502 are coupled to form a differential MESO logic cell.

Here, the term differential refers to the potential difference on each of two conductors c1 and c2 connecting spin orbit modules of MESO 501 that create voltage across ME layer (e.g., BFO2, SRO2, and STO2) of MESO 502, which is above a threshold voltage causing the ME layer of MESO 502 to charge or discharge to switch polarization and magnetization. As such, information is transmitted using two complementary signals, which is differential signaling.

In various embodiments, the ME material can one any one of the ME materials discussed with reference to ME layer 206a/b. Likewise, ferroelectric material for FM1_1 and FM2_1 can be any of the material for ferromagnets discussed with reference magnets 201 and 207. Here, the insulative FM material (FMi_1) can by any of the materials discussed with reference to semi-insulating FM material discussed with to various embodiments herein (e.g., semi-insulating magnets 209a/b). The conductive material can be any of the materials discussed with reference to non-FM conductors between the MESO cells such as charge conductors 205, 211a, 211b, etc.

In various embodiments, structures comprising STO, SRO, and BFO (e.g., STO1, STO2, SRO1, SRO2, BFO1, BFO2, etc.) are located at the bottom of the ferromagnet (e.g., FM1_1 or FM1_2), which is below spin orbital (SO) stack (e.g. STOt1 and LAO1). In some embodiments, three wire/via are connected to top of SO module. Via n1_1 is connected to the header transistor MN1 to power supply, vias a1 and b1 of MESO cell 501 connect to the top and bottom plates of ferroelectric capacitor in next stage (e.g., MESI cell 502). In some embodiments, to decouple current path of: (1) capacitor charging (e.g., a1→t1→b1→s2_2→c2) and (2) power supply to ground path (Vdd→n1_1→t1→n2_1→ground), an insulating/magnetic layer (e.g., FMi_1) is inserted into an original homogeneous ferromagnet. In this example, the magnetization directions of the magnets is along the y-axis (i.e., in-plane magnetization).

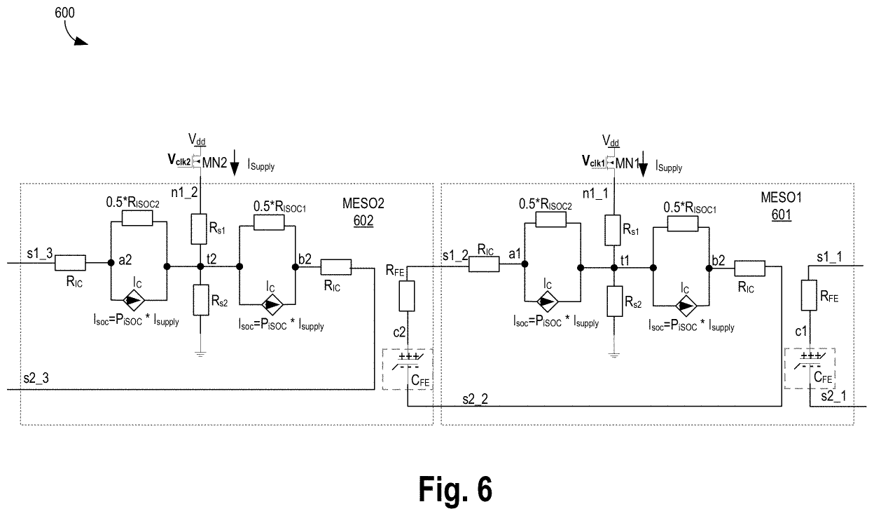

FIG. 6 illustrates a circuitry model 600 of the differential MESO logic 500 (comprising cells 601 and 602), in accordance with some embodiments. Similar to one-sided MESO models of FIGS. 3A-B, here the spin-to-charge conversion is described with R_{isoc} in parallel with current control current source. For example, the R_{isoc} (resistance model of the spin-orbit module) is split into two and placed on left and right for the respective MESO devices. Because of the differential signaling, two interconnect R_{IC} are used as well. R_{FE} here could contain the thickness resistance of magnet layers in general. The R_{FE} and C_{FE} would form the input circuit branch for each MESO device. The circuit model also suggests the independence of input and output circuitry.

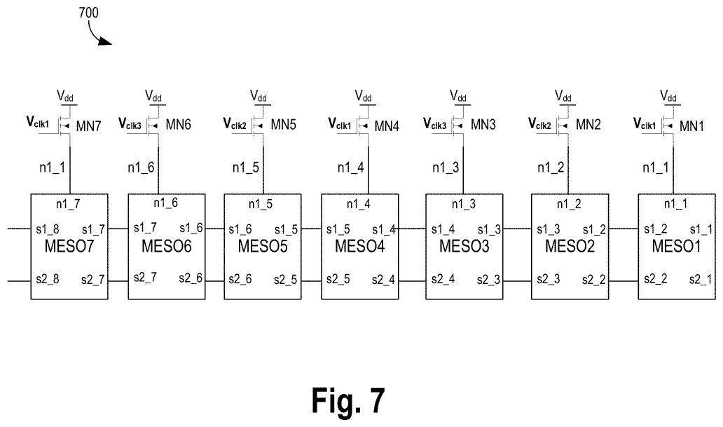

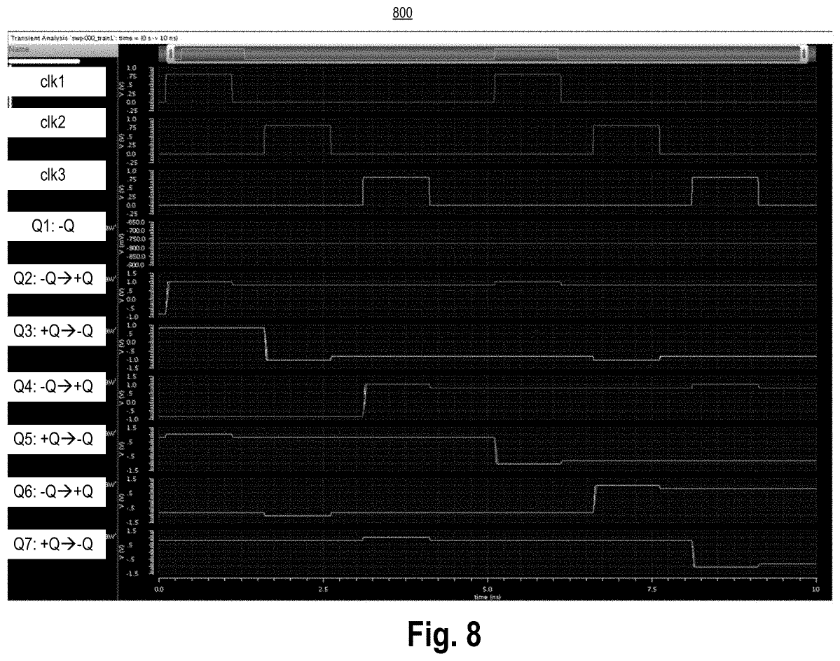

FIG. 7 illustrates model 700 of cascaded differential MESO logic devices, in accordance with some embodiments. Conductors such as s1_1, s2_1, s1_2, s2_2, and n1_1 for each cell are connected as shown. For example, s1_2 of MESO1 connects to s1) 2 of MESO2, and onwards.

In some embodiments, individual MESO cells of FIG. 5 are cascaded linearly as shown. In this example, seven MESO cells are cascaded forming a chain of differential MESO cells. Clocks Vclk1, Vclk2, and Vclk3 are non-overlapping clocks that allow data to propagate from MESO1 to MESO7 with fewer transistors than traditional cascaded MESO cells. For cascaded MESO 700, intermediate stage is not disturbed as resistive leakage path is cut even though footer transistor is taken out. In some embodiments, each stage in the cascade can switch at the rising edge of clock signal instead of two-clock overlapping. Meanwhile, MESO state (normalized charge Q) shows cleaner signal compared to traditional MESO cells that are cascaded.

FIG. 8 illustrates a set of plots 800 showing simulation or timing diagram of the model of FIG. 7, in accordance with some embodiments.

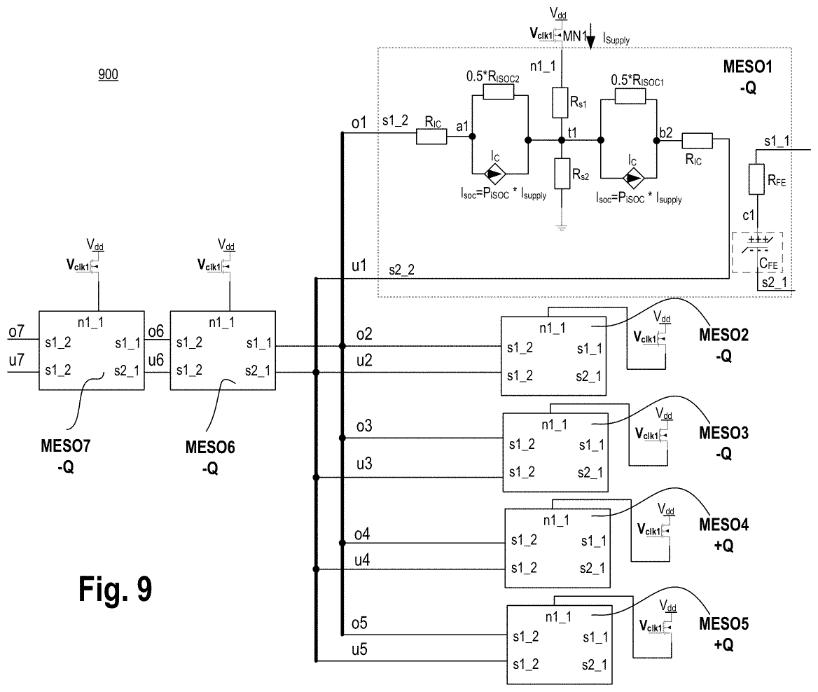

FIG. 9 illustrates a majority gate 900 of 5 inputs using the differential MESO logic devices, in accordance with some embodiments. The 5-input MESO can include any customized initial FE states. When clk1 is at high level, the 5-input MESO device will create voltage at the two joint output nodes and switch the ME of MESO6 via s1_1 and s2_1 of MESO6. In this specific case (also applied to different initial conditions), MESO1, MESO2, and MESO3 have −Q initially and MESO4 and MESO5 have +Q. Hence, the minority state is +Q and MESO6 switches from −Q from +Q when clk1 is enabled.

When clk2 is at high level, MESO6 is already +Q and will try to switch MESO7. In this case, MESO7 is already −Q and will be in the same state. One reason to have MESO7 (inverter) is to convert the entire circuit from minority gate to majority gate. The number of inputs could be less or more than five but is expected to be an odd number of inputs. With inputs, the majority gate circuit becomes more compact but may apply more demanding requirement on device and material properties.

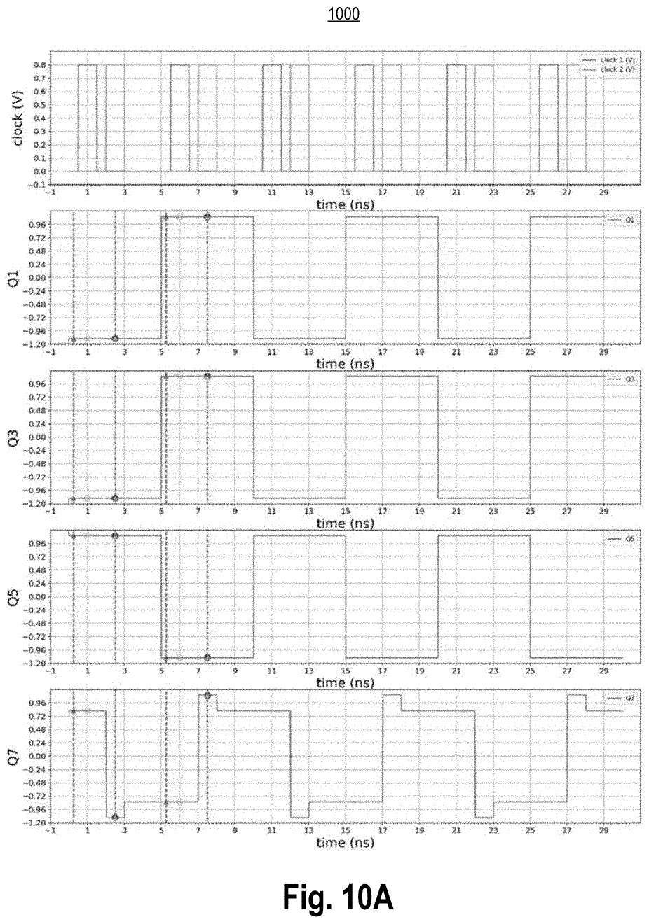

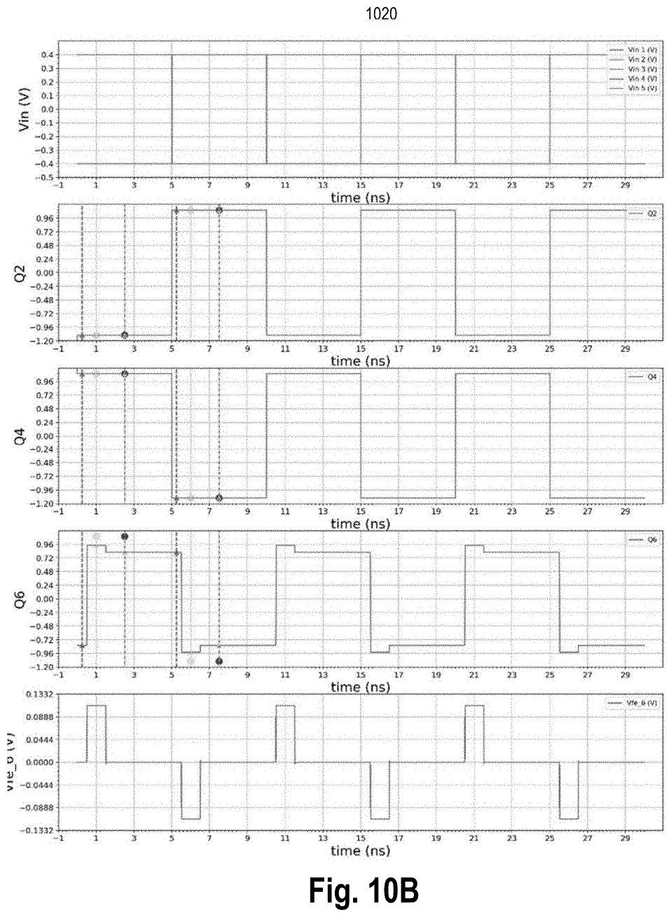

FIGS. 10A-B illustrate a set of plots 1000 and 1020 showing simulation of the majority gate of FIG. 9, in accordance with some embodiments. For 5-input minority gate, additional stage of MESO is used to mimic majority gate behavior. Here, 128 cases of different initial conditions are simulated and validated with Boolean algebra to produce truth table.

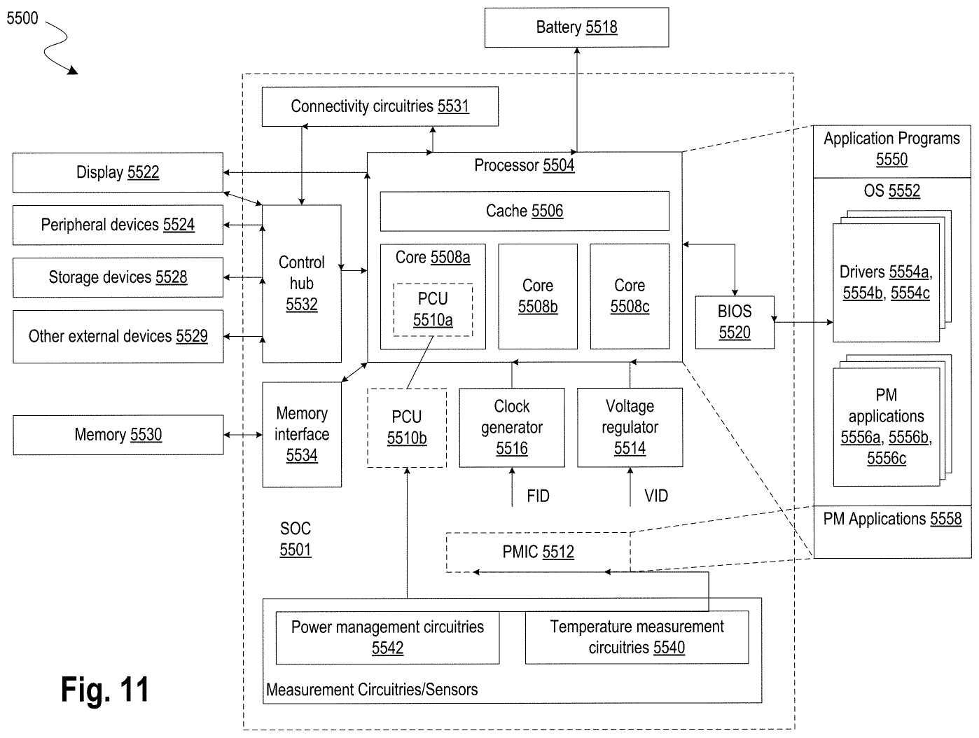

FIG. 11 illustrates a smart device or a computer system or a SoC (System-on-Chip) with a differential MESO device or logic in accordance with a power state of a coupled connected to the SoC, in accordance with some embodiments. It is pointed out that those elements of FIG. 11 having the same reference numbers (or names) as the elements of any other figure may operate or function in any manner similar to that described, but are not limited to such. Any block in this smart device can have the apparatus for dynamically optimizing battery charging voltage. In some embodiments, the scheme for dynamically optimizing battery charging voltage is stored as machine readable and executable instructions in a battery or any memory of the smart device.

In some embodiments, device 5500 represents an appropriate computing device, such as a computing tablet, a mobile phone or smart-phone, a laptop, a desktop, an Internet-of-Things (IOT) device, a server, a wearable device, a set-top box, a wireless-enabled e-reader, or the like. It will be understood that certain components are shown generally, and not all components of such a device are shown in device 5500.

In an example, the device 5500 comprises an SoC (System-on-Chip) 5501. An example boundary of the SoC 5501 is illustrated using dotted lines in FIG. 11, with some example components being illustrated to be included within SoC 5501—however, SoC 5501 may include any appropriate components of device 5500.

In some embodiments, device 5500 includes processor 5504. Processor 5504 can include one or more physical devices, such as microprocessors, application processors, microcontrollers, programmable logic devices, processing cores, or other processing means. The processing operations performed by processor 5504 include the execution of an operating platform or operating system on which applications and/or device functions are executed. The processing operations include operations related to I/O (input/output) with a human user or with other devices, operations related to power management, operations related to connecting computing device 5500 to another device, and/or the like. The processing operations may also include operations related to audio I/O and/or display I/O.

In some embodiments, processor 5504 includes multiple processing cores (also referred to as cores) 5508a, 5508b, 5508c. Although merely three cores 5508a, 5508b, 5508c are illustrated in FIG. 11, processor 5504 may include any other appropriate number of processing cores, e.g., tens, or even hundreds of processing cores. Processor cores 5508a, 5508b, 5508c may be implemented on a single integrated circuit (IC) chip. Moreover, the chip may include one or more shared and/or private caches, buses or interconnections, graphics and/or memory controllers, or other components.

In some embodiments, processor 5504 includes cache 5506. In an example, sections of cache 5506 may be dedicated to individual cores 5508 (e.g., a first section of cache 5506 dedicated to core 5508a, a second section of cache 5506 dedicated to core 5508b, and so on). In an example, one or more sections of cache 5506 may be shared among two or more of cores 5508. Cache 5506 may be split in different levels, e.g., level 1 (L1) cache, level 2 (L2) cache, level 3 (L3) cache, etc.

In some embodiments, processor core 5504 may include a fetch unit to fetch instructions (including instructions with conditional branches) for execution by the core 5504. The instructions may be fetched from any storage devices such as the memory 5530. Processor core 5504 may also include a decode unit to decode the fetched instruction. For example, the decode unit may decode the fetched instruction into a plurality of micro-operations. Processor core 5504 may include a schedule unit to perform various operations associated with storing decoded instructions. For example, the schedule unit may hold data from the decode unit until the instructions are ready for dispatch, e.g., until all source values of a decoded instruction become available. In one embodiment, the schedule unit may schedule and/or issue (or dispatch) decoded instructions to an execution unit for execution.

The execution unit may execute the dispatched instructions after they are decoded (e.g., by the decode unit) and dispatched (e.g., by the schedule unit). In an embodiment, the execution unit may include more than one execution unit (such as an imaging computational unit, a graphics computational unit, a general-purpose computational unit, etc.). The execution unit may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit.

Further, execution unit may execute instructions out-of-order. Hence, processor core 5504 may be an out-of-order processor core in one embodiment. Processor core 5504 may also include a retirement unit. The retirement unit may retire executed instructions after they are committed. In an embodiment, retirement of the executed instructions may result in processor state being committed from the execution of the instructions, physical registers used by the instructions being de-allocated, etc. Processor core 5504 may also include a bus unit to enable communication between components of processor core 5504 and other components via one or more buses. Processor core 5504 may also include one or more registers to store data accessed by various components of the core 5504 (such as values related to assigned app priorities and/or sub-system states (modes) association.

In some embodiments, device 5500 comprises connectivity circuitries 5531. For example, connectivity circuitries 5531 includes hardware devices (e.g., wireless and/or wired connectors and communication hardware) and/or software components (e.g., drivers, protocol stacks), e.g., to enable device 5500 to communicate with external devices. Device 5500 may be separate from the external devices, such as other computing devices, wireless access points or base stations, etc.

In an example, connectivity circuitries 5531 may include multiple different types of connectivity. To generalize, the connectivity circuitries 5531 may include cellular connectivity circuitries, wireless connectivity circuitries, etc. Cellular connectivity circuitries of connectivity circuitries 5531 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, 3rd Generation Partnership Project (3GPP) Universal Mobile Telecommunications Systems (UMTS) system or variations or derivatives, 3GPP Long-Term Evolution (LTE) system or variations or derivatives, 3GPP LTE-Advanced (LTE-A) system or variations or derivatives, Fifth Generation (5G) wireless system or variations or derivatives, 5G mobile networks system or variations or derivatives, 5G New Radio (NR) system or variations or derivatives, or other cellular service standards. Wireless connectivity circuitries (or wireless interface) of the connectivity circuitries 5531 refers to wireless connectivity that is not cellular, and can include personal area networks (such as Bluetooth, Near Field, etc.), local area networks (such as Wi-Fi), and/or wide area networks (such as WiMax), and/or other wireless communication. In an example, connectivity circuitries 5531 may include a network interface, such as a wired or wireless interface, e.g., so that a system embodiment may be incorporated into a wireless device, for example, a cell phone or personal digital assistant.

In some embodiments, device 5500 comprises control hub 5532, which represents hardware devices and/or software components related to interaction with one or more I/O devices. For example, processor 5504 may communicate with one or more of display 5522, one or more peripheral devices 5524, storage devices 5528, one or more other external devices 5529, etc., via control hub 5532. Control hub 5532 may be a chipset, a Platform Control Hub (PCH), and/or the like.

For example, control hub 5532 illustrates one or more connection points for additional devices that connect to device 5500, e.g., through which a user might interact with the system. For example, devices (e.g., devices 5529) that can be attached to device 5500 include microphone devices, speaker or stereo systems, audio devices, video systems or other display devices, keyboard or keypad devices, or other I/O devices for use with specific applications such as card readers or other devices.

As mentioned above, control hub 5532 can interact with audio devices, display 5522, etc. For example, input through a microphone or other audio device can provide input or commands for one or more applications or functions of device 5500. Additionally, audio output can be provided instead of, or in addition to display output. In another example, if display 5522 includes a touch screen, display 5522 also acts as an input device, which can be at least partially managed by control hub 5532. There can also be additional buttons or switches on computing device 5500 to provide I/O functions managed by control hub 5532. In one embodiment, control hub 5532 manages devices such as accelerometers, cameras, light sensors or other environmental sensors, or other hardware that can be included in device 5500. The input can be part of direct user interaction, as well as providing environmental input to the system to influence its operations (such as filtering for noise, adjusting displays for brightness detection, applying a flash for a camera, or other features).

In some embodiments, control hub 5532 may couple to various devices using any appropriate communication protocol, e.g., PCIe (Peripheral Component Interconnect Express), USB (Universal Serial Bus), Thunderbolt, High Definition Multimedia Interface (HDMI), Firewire, etc.

In some embodiments, display 5522 represents hardware (e.g., display devices) and software (e.g., drivers) components that provide a visual and/or tactile display for a user to interact with device 5500. Display 5522 may include a display interface, a display screen, and/or hardware device used to provide a display to a user. In some embodiments, display 5522 includes a touch screen (or touch pad) device that provides both output and input to a user. In an example, display 5522 may communicate directly with the processor 5504. Display 5522 can be one or more of an internal display device, as in a mobile electronic device or a laptop device or an external display device attached via a display interface (e.g., DisplayPort, etc.). In one embodiment display 5522 can be a head mounted display (HMD) such as a stereoscopic display device for use in virtual reality (VR) applications or augmented reality (AR) applications.

In some embodiments, and although not illustrated in the figure, in addition to (or instead of) processor 5504, device 5500 may include Graphics Processing Unit (GPU) comprising one or more graphics processing cores, which may control one or more aspects of displaying contents on display 5522.

Control hub 5532 (or platform controller hub) may include hardware interfaces and connectors, as well as software components (e.g., drivers, protocol stacks) to make peripheral connections, e.g., to peripheral devices 5524.

It will be understood that device 5500 could both be a peripheral device to other computing devices, as well as have peripheral devices connected to it. Device 5500 may have a “docking” connector to connect to other computing devices for purposes such as managing (e.g., downloading and/or uploading, changing, synchronizing) content on device 5500. Additionally, a docking connector can allow device 5500 to connect to certain peripherals that allow computing device 5500 to control content output, for example, to audiovisual or other systems.

In addition to a proprietary docking connector or other proprietary connection hardware, device 5500 can make peripheral connections via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, connectivity circuitries 5531 may be coupled to control hub 5532, e.g., in addition to, or instead of, being coupled directly to the processor 5504. In some embodiments, display 5522 may be coupled to control hub 5532, e.g., in addition to, or instead of, being coupled directly to processor 5504.

In some embodiments, device 5500 comprises memory 5530 coupled to processor 5504 via memory interface 5534. Memory 5530 includes memory devices for storing information in device 5500.

In some embodiments, memory 5530 includes apparatus to maintain stable clocking as described with reference to various embodiments. Memory can include nonvolatile (state does not change if power to the memory device is interrupted) and/or volatile (state is indeterminate if power to the memory device is interrupted) memory devices. Memory device 5530 can be a dynamic random-access memory (DRAM) device, a static random-access memory (SRAM) device, flash memory device, phase-change memory device, or some other memory device having suitable performance to serve as process memory. In one embodiment, memory 5530 can operate as system memory for device 5500, to store data and instructions for use when the one or more processors 5504 executes an application or process. Memory 5530 can store application data, user data, music, photos, documents, or other data, as well as system data (whether long-term or temporary) related to the execution of the applications and functions of device 5500.

Elements of various embodiments and examples are also provided as a machine-readable medium (e.g., memory 5530) for storing the computer-executable instructions (e.g., instructions to implement any other processes discussed herein). The machine-readable medium (e.g., memory 5530) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, device 5500 comprises temperature measurement circuitries 5540, e.g., for measuring temperature of various components of device 5500. In an example, temperature measurement circuitries 5540 may be embedded, or coupled or attached to various components, whose temperature are to be measured and monitored. For example, temperature measurement circuitries 5540 may measure temperature of (or within) one or more of cores 5508a, 5508b, 5508c, voltage regulator 5514, memory 5530, a mother-board of SoC 5501, and/or any appropriate component of device 5500. In some embodiments, temperature measurement circuitries 5540 include a low power hybrid reverse (LPHR) bandgap reference (BGR) and digital temperature sensor (DTS), which utilizes subthreshold metal oxide semiconductor (MOS) transistor and the PNP parasitic Bi-polar Junction Transistor (BJT) device to form a reverse BGR that serves as the base for configurable BGR or DTS operating modes. The LPHR architecture uses low-cost MOS transistors and the standard parasitic PNP device. Based on a reverse bandgap voltage, the LPHR can work as a configurable BGR. By comparing the configurable BGR with the scaled base-emitter voltage, the circuit can also perform as a DTS with a linear transfer function with single-temperature trim for high accuracy.

In some embodiments, device 5500 comprises power measurement circuitries 5542, e.g., for measuring power consumed by one or more components of the device 5500. In an example, in addition to, or instead of, measuring power, the power measurement circuitries 5542 may measure voltage and/or current. In an example, the power measurement circuitries 5542 may be embedded, or coupled or attached to various components, whose power, voltage, and/or current consumption are to be measured and monitored. For example, power measurement circuitries 5542 may measure power, current and/or voltage supplied by one or more voltage regulators 5514, power supplied to SoC 5501, power supplied to device 5500, power consumed by processor 5504 (or any other component) of device 5500, etc.

In some embodiments, device 5500 comprises one or more voltage regulator circuitries, generally referred to as voltage regulator (VR) 5514. VR 5514 generates signals at appropriate voltage levels, which may be supplied to operate any appropriate components of the device 5500. Merely as an example, VR 5514 is illustrated to be supplying signals to processor 5504 of device 5500. In some embodiments, VR 5514 receives one or more Voltage Identification (VID) signals, and generates the voltage signal at an appropriate level, based on the VID signals. Various type of VRs may be utilized for the VR 5514. For example, VR 5514 may include a “buck” VR, “boost” VR, a combination of buck and boost VRs, low dropout (LDO) regulators, switching DC-DC regulators, constant-on-time controller-based DC-DC regulator, etc. Buck VR is generally used in power delivery applications in which an input voltage needs to be transformed to an output voltage in a ratio that is smaller than unity. Boost VR is generally used in power delivery applications in which an input voltage needs to be transformed to an output voltage in a ratio that is larger than unity. In some embodiments, each processor core has its own VR, which is controlled by PCU 5510a/b and/or PMIC 5512. In some embodiments, each core has a network of distributed LDOs to provide efficient control for power management. The LDOs can be digital, analog, or a combination of digital or analog LDOs. In some embodiments, VR 5514 includes current tracking apparatus to measure current through power supply rail(s).

In some embodiments, VR 5514 includes a digital control scheme to manage states of a proportional-integral-derivative (PID) filter (also known as a digital Type-III compensator). The digital control scheme controls the integrator of the PID filter to implement non-linear control of saturating the duty cycle during which the proportional and derivative terms of the PID are set to 0 while the integrator and its internal states (previous values or memory) is set to a duty cycle that is the sum of the current nominal duty cycle plus a deltaD. The deltaD is the maximum duty cycle increment that is used to regulate a voltage regulator from ICCmin to ICCmax and is a configuration register that can be set post silicon. A state machine moves from a non-linear all ON state (which brings the output voltage Vout back to a regulation window) to an open loop duty cycle which maintains the output voltage slightly higher than the required reference voltage Vref. After a certain period in this state of open loop at the commanded duty cycle, the state machine then ramps down the open loop duty cycle value until the output voltage is close to the Vref commanded. As such, output chatter on the output supply from VR 5514 is completely eliminated (or substantially eliminated) and there is merely a single undershoot transition which could lead to a guaranteed Vmin based on a comparator delay and the di/dt of the load with the available output decoupling capacitance.

In some embodiments, VR 5514 includes a separate self-start controller, which is functional without fuse and/or trim information. The self-start controller protects VR 5514 against large inrush currents and voltage overshoots, while being capable of following a variable VID (voltage identification) reference ramp imposed by the system. In some embodiments, the self-start controller uses a relaxation oscillator built into the controller to set the switching frequency of the buck converter. The oscillator can be initialized using either a clock or current reference to be close to a desired operating frequency. The output of VR 5514 is coupled weakly to the oscillator to set the duty cycle for closed loop operation. The controller is naturally biased such that the output voltage is always slightly higher than the set point, eliminating the need for any process, voltage, and/or temperature (PVT) imposed trims.

In some embodiments, device 5500 comprises one or more clock generator circuitries, generally referred to as clock generator 5516. Clock generator 5516 generates clock signals at appropriate frequency levels, which may be supplied to any appropriate components of device 5500. Merely as an example, clock generator 5516 is illustrated to be supplying clock signals to processor 5504 of device 5500. In some embodiments, clock generator 5516 receives one or more Frequency Identification (FID) signals, and generates the clock signals at an appropriate frequency, based on the FID signals.

In some embodiments, device 5500 comprises battery 5518 supplying power to various components of device 5500. Merely as an example, battery 5518 is illustrated to be supplying power to processor 5504. Although not illustrated in the figures, device 5500 may comprise a charging circuitry, e.g., to recharge the battery, based on Alternating Current (AC) power supply received from an AC adapter.

In some embodiments, battery 5518 periodically checks an actual battery capacity or energy with charge to a preset voltage (e.g., 4.1 V). The battery then decides of the battery capacity or energy. If the capacity or energy is insufficient, then an apparatus in or associated with the battery slightly increases charging voltage to a point where the capacity is sufficient (e.g. from 4.1 V to 4.11 V). The process of periodically checking and slightly increase charging voltage is performed until charging voltage reaches specification limit (e.g., 4.2 V). The scheme described herein has benefits such as battery longevity can be extended, risk of insufficient energy reserve can be reduced, burst power can be used as long as possible, and/or even higher burst power can be used.

In some embodiments, the charging circuitry (e.g., 5518) comprises a buck-boost converter. This buck-boost converter comprises DrMOS or DrGaN devices used in place of half-bridges for traditional buck-boost converters. Various embodiments here are described with reference to DrMOS. However, the embodiments are applicable to DrGaN. The DrMOS devices allow for better efficiency in power conversion due to reduced parasitic and optimized MOSFET packaging. Since the dead-time management is internal to the DrMOS, the dead-time management is more accurate than for traditional buck-boost converters leading to higher efficiency in conversion. Higher frequency of operation allows for smaller inductor size, which in turn reduces the z-height of the charger comprising the DrMOS based buck-boost converter. The buck-boost converter of various embodiments comprises dual-folded bootstrap for DrMOS devices. In some embodiments, in addition to the traditional bootstrap capacitors, folded bootstrap capacitors are added that cross-couple inductor nodes to the two sets of DrMOS switches.

In some embodiments, device 5500 comprises Power Control Unit (PCU) 5510 (also referred to as Power Management Unit (PMU), Power Management Controller (PMC), Power Unit (p-unit), etc.). In an example, some sections of PCU 5510 may be implemented by one or more processing cores 5508, and these sections of PCU 5510 are symbolically illustrated using a dotted box and labelled PCU 5510a. In an example, some other sections of PCU 5510 may be implemented outside the processing cores 5508, and these sections of PCU 5510 are symbolically illustrated using a dotted box and labelled as PCU 5510b. PCU 5510 may implement various power management operations for device 5500. PCU 5510 may include hardware interfaces, hardware circuitries, connectors, registers, etc., as well as software components (e.g., drivers, protocol stacks), to implement various power management operations for device 5500.

In various embodiments, PCU or PMU 5510 is organized in a hierarchical manner forming a hierarchical power management (HPM). HPM of various embodiments builds a capability and infrastructure that allows for package level management for the platform, while still catering to islands of autonomy that might exist across the constituent die in the package. HPM does not assume a pre-determined mapping of physical partitions to domains. An HPM domain can be aligned with a function integrated inside a dielet, to a dielet boundary, to one or more dielets, to a companion die, or even a discrete CXL device. HPM addresses integration of multiple instances of the same die, mixed with proprietary functions or 3rd party functions integrated on the same die or separate die, and even accelerators connected via CXL (e.g., Flexbus) that may be inside the package, or in a discrete form factor.

HPM enables designers to meet the goals of scalability, modularity, and late binding. HPM also allows PMU functions that may already exist on other dice to be leveraged, instead of being disabled in the flat scheme. HPM enables management of any arbitrary collection of functions independent of their level of integration. HPM of various embodiments is scalable, modular, works with symmetric multi-chip processors (MCPs), and works with asymmetric MCPs. For example, HPM does not need a signal PM controller and package infrastructure to grow beyond reasonable scaling limits. HPM enables late addition of a die in a package without the need for change in the base die infrastructure. HPM addresses the need of disaggregated solutions having dies of different process technology nodes coupled in a single package. HPM also addresses the needs of companion die integration solutions—on and off package.

In various embodiments, each die (or dielet) includes a power management unit (PMU) or p-unit. For example, processor dies can have a supervisor p-unit, supervisee p-unit, or a dual role supervisor/supervisee p-unit. In some embodiments, an I/O die has its own dual role p-unit such as supervisor and/or supervisee p-unit. The p-units in each die can be instances of a generic p-unit. In one such example, all p-units have the same capability and circuits, but are configured (dynamically or statically) to take a role of a supervisor, supervisee, and/or both. In some embodiments, the p-units for compute dies are instances of a compute p-unit while p-units for IO dies are instances of an IO p-unit different from the compute p-unit. Depending on the role, p-unit acquires specific responsibilities to manage power of the multichip module and/or computing platform. While various p-units are described for dies in a multichip module or system-on-chip, a p-unit can also be part of an external device such as I/O device.

Here, the various p-units do not have to be the same. The HPM architecture can operate very different types of p-units. One common feature for the p-units is that they are expected to receive HPM messages and are expected to be able to comprehend them. In some embodiments, the p-unit of IO dies may be different than the p-unit of the compute dies. For example, the number of register instances of each class of register in the IO p-unit is different than those in the p-units of the compute dies. An IO die has the capability of being an HPM supervisor for CXL connected devices, but compute die may not need to have that capability. The IO and computes dice also have different firmware flows and possibly different firmware images. These are choices that an implementation can make. An HPM architecture can choose to have one superset firmware image and selectively execute flows that are relevant to the die type the firmware is associated with. Alternatively, there can be a customer firmware for each p-unit type; it can allow for more streamlined sizing of the firmware storage requirements for each p-unit type.

The p-unit in each die can be configured as a supervisor p-unit, supervisee p-unit or with a dual role of supervisor/supervisee. As such, p-units can perform roles of supervisor or supervisee for various domains. In various embodiments, each instance of p-unit is capable of autonomously managing local dedicated resources and contains structures to aggregate data and communicate between instances to enable shared resource management by the instance configured as the shared resource supervisor. A message and wire-based infrastructure is provided that can be duplicated and configured to facilitate management and flows between multiple p-units.

In some embodiments, power and thermal thresholds are communicated by a supervisor p-unit to supervisee p-units. For example, a supervisor p-unit learns of the workload (present and future) of each die, power measurements of each die, and other parameters (e.g., platform level power boundaries) and determines new power limits for each die. These power limits are then communicated by supervisor p-units to the supervisee p-units via one or more interconnects and fabrics. In some embodiments, a fabric indicates a group of fabrics and interconnect including a first fabric, a second fabric, and a fast response interconnect. In some embodiments, the first fabric is used for common communication between a supervisor p-unit and a supervisee p-unit. These common communications include change in voltage, frequency, and/or power state of a die which is planned based on a number of factors (e.g., future workload, user behavior, etc.). In some embodiments, the second fabric is used for higher priority communication between supervisor p-unit and supervisee p-unit. Example of higher priority communication include a message to throttle because of a possible thermal runaway condition, reliability issue, etc. In some embodiments, a fast response interconnect is used for communicating fast or hard throttle of all dies. In this case, a supervisor p-unit may send a fast throttle message to all other p-units, for example. In some embodiments, a fast response interconnect is a legacy interconnect whose function can be performed by the second fabric.

The HPM architecture of various embodiments enables scalability, modularity, and late binding of symmetric and/or asymmetric dies. Here, symmetric dies are dies of same size, type, and/or function, while asymmetric dies are dies of different size, type, and/or function. Hierarchical approach also allows PMU functions that may already exist on other dice to be leveraged, instead of being disabled in the traditional flat power management scheme. HPM does not assume a pre-determined mapping of physical partitions to domains. An HPM domain can be aligned with a function integrated inside a dielet, to a dielet boundary, to one or more dielets, to a companion die, or even a discrete CXL device. HPM enables management of any arbitrary collection of functions independent of their level of integration. In some embodiments, a p-unit is declared a supervisor p-unit based on one or more factors. These factors include memory size, physical constraints (e.g., number of pin-outs), and locations of sensors (e.g., temperature, power consumption, etc.) to determine physical limits of the processor.

The HPM architecture of various embodiments, provides a means to scale power management so that a single p-unit instance does not need to be aware of the entire processor. This enables power management at a smaller granularity and improves response times and effectiveness. Hierarchical structure maintains a monolithic view to the user. For example, at an operating system (OS) level, HPM architecture gives the OS a single PMU view even though the PMU is physically distributed in one or more supervisor-supervisee configurations.

In some embodiments, the HPM architecture is centralized where one supervisor controls all supervisees. In some embodiments, the HPM architecture is decentralized, wherein various p-units in various dies control overall power management by peer-to-peer communication. In some embodiments, the HPM architecture is distributed where there are different supervisors for different domains. One example of a distributed architecture is a tree-like architecture.

In some embodiments, device 5500 comprises Power Management Integrated Circuit (PMIC) 5512, e.g., to implement various power management operations for device 5500. In some embodiments, PMIC 5512 is a Reconfigurable Power Management ICs (RPMICs) and/or an IMVP (Intel® Mobile Voltage Positioning). In an example, the PMIC is within an IC die separate from processor 5504. The may implement various power management operations for device 5500. PMIC 5512 may include hardware interfaces, hardware circuitries, connectors, registers, etc., as well as software components (e.g., drivers, protocol stacks), to implement various power management operations for device 5500.

In an example, device 5500 comprises one or both PCU 5510 or PMIC 5512. In an example, any one of PCU 5510 or PMIC 5512 may be absent in device 5500, and hence, these components are illustrated using dotted lines.

Various power management operations of device 5500 may be performed by PCU 5510, by PMIC 5512, or by a combination of PCU 5510 and PMIC 5512. For example, PCU 5510 and/or PMIC 5512 may select a power state (e.g., P-state) for various components of device 5500. For example, PCU 5510 and/or PMIC 5512 may select a power state (e.g., in accordance with the ACPI (Advanced Configuration and Power Interface) specification) for various components of device 5500. Merely as an example, PCU 5510 and/or PMIC 5512 may cause various components of the device 5500 to transition to a sleep state, to an active state, to an appropriate C state (e.g., C0 state, or another appropriate C state, in accordance with the ACPI specification), etc. In an example, PCU 5510 and/or PMIC 5512 may control a voltage output by VR 5514 and/or a frequency of a clock signal output by the clock generator, e.g., by outputting the VID signal and/or the FID signal, respectively. In an example, PCU 5510 and/or PMIC 5512 may control battery power usage, charging of battery 5518, and features related to power saving operation.

The clock generator 5516 can comprise a phase locked loop (PLL), frequency locked loop (FLL), or any suitable clock source. In some embodiments, each core of processor 5504 has its own clock source. As such, each core can operate at a frequency independent of the frequency of operation of the other core. In some embodiments, PCU 5510 and/or PMIC 5512 performs adaptive or dynamic frequency scaling or adjustment. For example, clock frequency of a processor core can be increased if the core is not operating at its maximum power consumption threshold or limit. In some embodiments, PCU 5510 and/or PMIC 5512 determines the operating condition of each core of a processor, and opportunistically adjusts frequency and/or power supply voltage of that core without the core clocking source (e.g., PLL of that core) losing lock when the PCU 5510 and/or PMIC 5512 determines that the core is operating below a target performance level. For example, if a core is drawing current from a power supply rail less than a total current allocated for that core or processor 5504, then PCU 5510 and/or PMIC 5512 can temporality increase the power draw for that core or processor 5504 (e.g., by increasing clock frequency and/or power supply voltage level) so that the core or processor 5504 can perform at higher performance level. As such, voltage and/or frequency can be increased temporality for processor 5504 without violating product reliability.

In an example, PCU 5510 and/or PMIC 5512 may perform power management operations, e.g., based at least in part on receiving measurements from power measurement circuitries 5542, temperature measurement circuitries 5540, charge level of battery 5518, and/or any other appropriate information that may be used for power management. To that end, PMIC 5512 is communicatively coupled to one or more sensors to sense/detect various values/variations in one or more factors having an effect on power/thermal behavior of the system/platform. Examples of the one or more factors include electrical current, voltage droop, temperature, operating frequency, operating voltage, power consumption, inter-core communication activity, etc. One or more of these sensors may be provided in physical proximity (and/or thermal contact/coupling) with one or more components or logic/IP blocks of a computing system. Additionally, sensor(s) may be directly coupled to PCU 5510 and/or PMIC 5512 in at least one embodiment to allow PCU 5510 and/or PMIC 5512 to manage processor core energy at least in part based on value(s) detected by one or more of the sensors.

Also illustrated is an example software stack of device 5500 (although not all elements of the software stack are illustrated). Merely as an example, processors 5504 may execute application programs 5550, Operating System 5552, one or more Power Management (PM) specific application programs (e.g., generically referred to as PM applications 5558), and/or the like. PM applications 5558 may also be executed by the PCU 5510 and/or PMIC 5512. OS 5552 may also include one or more PM applications 5556a, 5556b, 5556c. The OS 5552 may also include various drivers 5554a, 5554b, 5554c, etc., some of which may be specific for power management purposes. In some embodiments, device 5500 may further comprise a Basic Input/output System (BIOS) 5520. BIOS 5520 may communicate with OS 5552 (e.g., via one or more drivers 5554), communicate with processors 5504, etc.

For example, one or more of PM applications 5558, 5556, drivers 5554, BIOS 5520, etc. may be used to implement power management specific tasks, e.g., to control voltage and/or frequency of various components of device 5500, to control wake-up state, sleep state, and/or any other appropriate power state of various components of device 5500, control battery power usage, charging of the battery 5518, features related to power saving operation, etc.

In some embodiments, battery 5518 is a Li-metal battery with a pressure chamber to allow uniform pressure on a battery. The pressure chamber is supported by metal plates (such as pressure equalization plate) used to give uniform pressure to the battery. The pressure chamber may include pressured gas, elastic material, spring plate, etc. The outer skin of the pressure chamber is free to bow, restrained at its edges by (metal) skin, but still exerts a uniform pressure on the plate that is compressing the battery cell. The pressure chamber gives uniform pressure to battery, which is used to enable high-energy density battery with, for example, 20% more battery life.

In some embodiments, pCode executing on PCU 5510a/b has a capability to enable extra compute and telemetries resources for the runtime support of the pCode. Here pCode refers to a firmware executed by PCU 5510a/b to manage performance of the 5501. For example, pCode may set frequencies and appropriate voltages for the processor. Part of the pCode are accessible via OS 5552. In various embodiments, mechanisms and methods are provided that dynamically change an Energy Performance Preference (EPP) value based on workloads, user behavior, and/or system conditions. There may be a well-defined interface between OS 5552 and the pCode. The interface may allow or facilitate the software configuration of several parameters and/or may provide hints to the pCode. As an example, an EPP parameter may inform a pCode algorithm as to whether performance or battery life is more important.

This support may be done as well by the OS 5552 by including machine-learning support as part of OS 5552 and either tuning the EPP value that the OS hints to the hardware (e.g., various components of SoC 5501) by machine-learning prediction, or by delivering the machine-learning prediction to the pCode in a manner similar to that done by a Dynamic Tuning Technology (DTT) driver. In this model, OS 5552 may have visibility to the same set of telemetries as are available to a DTT. As a result of a DTT machine-learning hint setting, pCode may tune its internal algorithms to achieve optimal power and performance results following the machine-learning prediction of activation type. The pCode as example may increase the responsibility for the processor utilization change to enable fast response for user activity, or may increase the bias for energy saving either by reducing the responsibility for the processor utilization or by saving more power and increasing the performance lost by tuning the energy saving optimization. This approach may facilitate saving more battery life in case the types of activities enabled lose some performance level over what the system can enable. The pCode may include an algorithm for dynamic EPP that may take the two inputs, one from OS 5552 and the other from software such as DTT, and may selectively choose to provide higher performance and/or responsiveness. As part of this method, the pCode may enable in the DTT an option to tune its reaction for the DTT for different types of activity.

In some embodiments, pCode improves the performance of the SoC in battery mode. In some embodiments, pCode allows drastically higher SoC peak power limit levels (and thus higher Turbo performance) in battery mode. In some embodiments, pCode implements power throttling and is part of Intel's Dynamic Tuning Technology (DTT). In various embodiments, the peak power limit is referred to PL4. However, the embodiments are applicable to other peak power limits. In some embodiments, pCode sets the Vth threshold voltage (the voltage level at which the platform will throttle the SoC) in such a way as to prevent the system from unexpected shutdown (or black screening). In some embodiments, pCode calculates the Psoc,pk SoC Peak Power Limit (e.g., PL4), according to the threshold voltage (Vth). These are two dependent parameters, if one is set, the other can be calculated. pCode is used to optimally set one parameter (Vth) based on the system parameters, and the history of the operation. In some embodiments, pCode provides a scheme to dynamically calculate the throttling level (Psoc,th) based on the available battery power (which changes slowly) and set the SoC throttling peak power (Psoc,th). In some embodiments, pCode decides the frequencies and voltages based on Psoc,th. In this case, throttling events have less negative effect on the SoC performance Various embodiments provide a scheme which allows maximum performance (Pmax) framework to operate.

In some embodiments, VR 5514 includes a current sensor to sense and/or measure current through a high-side switch of VR 5514. In some embodiments the current sensor uses an amplifier with capacitively coupled inputs in feedback to sense the input offset of the amplifier, which can be compensated for during measurement. In some embodiments, the amplifier with capacitively coupled inputs in feedback is used to operate the amplifier in a region where the input common-mode specifications are relaxed, so that the feedback loop gain and/or bandwidth is higher. In some embodiments, the amplifier with capacitively coupled inputs in feedback is used to operate the sensor from the converter input voltage by employing high-PSRR (power supply rejection ratio) regulators to create a local, clean supply voltage, causing less disruption to the power grid in the switch area. In some embodiments, a variant of the design can be used to sample the difference between the input voltage and the controller supply, and recreate that between the drain voltages of the power and replica switches. This allows the sensor to not be exposed to the power supply voltage. In some embodiments, the amplifier with capacitively coupled inputs in feedback is used to compensate for power delivery network related (PDN-related) changes in the input voltage during current sensing.

Some embodiments use three components to adjust the peak power of SoC 5501 based on the states of a USB TYPE-C device 5529. These components include OS Peak Power Manager (part of OS 5552), USB TYPE-C Connector Manager (part of OS 5552), and USB TYPE-C Protocol Device Driver (e.g., one of drivers 5554a, 5554b, 5554c). In some embodiments, the USB TYPE-C Connector Manager sends a synchronous request to the OS Peak Power Manager when a USB TYPE-C power sink device is attached or detached from SoC 5501, and the USB TYPE-C Protocol Device Driver sends a synchronous request to the Peak Power Manager when the power sink transitions device state. In some embodiments, the Peak Power Manager takes power budget from the CPU when the USB TYPE-C connector is attached to a power sink and is active (e.g., high power device state). In some embodiments, the Peak Power Manager gives back the power budget to the CPU for performance when the USB TYPE-C connector is either detached or the attached and power sink device is idle (lowest device state).

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process. The examples can be combined in any combinations. For example, example 4 can be combined with example 2.

Example 1: An apparatus comprising: a first cell comprising a first magnetoelectric material, a first spin orbit material, and a first magnet, wherein the first magnet is between the first spin orbit material and the first magnetoelectric material; a second cell comprising a second magnetoelectric material, a second spin orbit material, and a second magnet, wherein the second magnet is between the second spin orbit material and the second magnetoelectric material; a first conductor coupled to the first spin orbit material and a first terminal of the second magnetoelectric material; and a second conductor coupled to the first spin orbit material and a second terminal of the second magnetoelectric material.

Example 2: The apparatus of example 1, wherein the first cell comprises: a first structure comprising the first magnetoelectric material; a second structure comprising the first magnet, wherein the second structure is adjacent to the first structure; and a third structure comprising the first spin orbit material, wherein the third structure is adjacent to the second structure, wherein the second structure is between the first structure and third structure.

Example 3: The apparatus of claim 2, wherein the second cell comprises: a fourth structure comprising the second magnetoelectric material; a fifth structure comprising the second magnet, wherein the fifth structure is adjacent to the fourth structure; and a sixth structure comprising the second spin orbit material, wherein the sixth structure is adjacent to the fifth structure, wherein the fifth structure is between the fourth structure and sixth structure.

Example 4: The apparatus of example 3, wherein the third or sixth structures include one or more of: β-Ta, β-W, W, Pt, Cu doped with Iridium, Cu doped with Bismuth, or Cu doped an element of 3d, 4d, 5d, 4f, or 5f of periodic table groups.

Example 5: The apparatus of example 3, wherein the first or fourth structures include BFO, SRO, and STO.

Example 6: The apparatus of example 3 comprises: a first transistor controllable by a first phase of a clock, wherein the first transistor is coupled to the third structure; and a second transistor controllable by a second phase of the clock, wherein the second transistor is coupled to sixth structure, wherein the first phase and second phase are different and do not overlap.

Example 7: The apparatus of example 3, wherein the first magnet is a first ferromagnet, and wherein the second structure comprises: a second ferroelectric magnet; and an insulative ferroelectric magnet between the first ferroelectric magnet and the second ferroelectric magnet.

Example 8: The apparatus of example 1, wherein the first or second magnetoelectric material include one or more of: BiFeO₃, LuFeO₂, LuFe₂O₄, or La doped BiFeO₃, or wherein the multiferroic material includes one of: Bi, Fe, O, Lu, or La.

Example 9: The apparatus of example 1, wherein the first or second magnets include a paramagnet or a ferromagnet, or wherein the first and second magnets comprises a material which includes one or more of: Pt, Pd, W, Ce, Al, Li, Mg, Na, Cr, O, Co, Dy, Er, Eu, Gd, Fe, Nd, K, Pr, Sm, Tb, Tm, or V.

Example 10: The apparatus of example 1, wherein the first or second magnets include one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, or Ru.

Example 11: An apparatus comprising: a first differential cell comprising a first magnetoelectric material, a first spin orbit material, and a first magnet, coupled together; and a second differential cell comprising a second magnetoelectric material, a second spin orbit material, and a second magnet coupled together, wherein the first spin orbit material is coupled to a first terminal of the second magnetoelectric material and a second terminal of the second magnetoelectric material.

Example 12: The apparatus of example 11, wherein the first or second magnets include a paramagnet or a ferromagnet, or wherein the first and second magnets comprises a material which includes one or more of: Pt, Pd, W, Ce, Al, Li, Mg, Na, Cr, O, Co, Dy, Er, Eu, Gd, Fe, Nd, K, Pr, Sm, Tb, Tm, or V.

Example 13: The apparatus of example 11, wherein the first or second magnets include one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, Ru.

Example 14: The apparatus of example 11 comprises: a first transistor controllable by a first phase of a clock, wherein the first transistor is coupled to the first spin orbit material; and a second transistor controllable by a second phase of the clock, wherein the second transistor is coupled to the second material, wherein the first phase and second phase are different and do not overlap.

Example 15: The apparatus of example 11, wherein the first or second magnetoelectric material include one or more of: BiFeO₃, LuFeO₂, LuFe₂O₄, or La doped BiFeO₃, or wherein the multiferroic material includes one of: Bi, Fe, O, Lu, or La.

Example 16: A system comprising: a memory; a processor coupled to the memory; and a wireless interface to allow the processor to communicate with another device, wherein the processor includes: a first differential cell comprising a first magnetoelectric material, a first spin orbit material, and a first magnet, coupled together; and a second differential cell comprising a second magnetoelectric material, a second spin orbit material, and a second magnet coupled together, wherein the first spin orbit material is coupled to a first terminal of the second magnetoelectric material and a second terminal of the second magnetoelectric material.

Example 17: The system of example 16, wherein the first or second magnets include a paramagnet or a ferromagnet, or wherein the first and second magnets comprises a material which includes one or more of: Pt, Pd, W, Ce, Al, Li, Mg, Na, Cr, O, Co, Dy, Er, Eu, Gd, Fe, Nd, K, Pr, Sm, Tb, Tm, or V.

Example 18: The system of example 16, wherein the first or second magnets include one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, or Ru.

Example 19: The system of example 16, wherein the processor comprises: a first transistor controllable by a first phase of a clock, wherein the first transistor is coupled to the first spin orbit material; and a second transistor controllable by a second phase of the clock, wherein the second transistor is coupled to the second material, wherein the first phase and second phase are different and do not overlap.

Example 20: The system of example 16, wherein the first or second magnetoelectric material include one or more of: BiFeO₃, LuFeO₂, LuFe₂O₄, or La doped BiFeO₃, or wherein the multiferroic material includes one of: Bi, Fe, O, Lu, or La.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus comprising:
a first cell comprising a first magnetoelectric material, a first spin orbit material, and a first magnet, wherein the first magnet is between the first spin orbit material and the first magnetoelectric material;
a second cell comprising a second magnetoelectric material, a second spin orbit material, and a second magnet, wherein the second magnet is between the second spin orbit material and the second magnetoelectric material;
a first conductor coupled to the first spin orbit material and a first terminal of the second magnetoelectric material; and
a second conductor coupled to the first spin orbit material and a second terminal of the second magnetoelectric material.

2. The apparatus of claim 1, wherein the first cell comprises:
a first structure comprising the first magnetoelectric material;
a second structure comprising the first magnet, wherein the second structure is adjacent to the first structure; and
a third structure comprising the first spin orbit material, wherein the third structure is adjacent to the second structure, wherein the second structure is between the first structure and third structure.

3. The apparatus of claim 2, wherein the second cell comprises:
a fourth structure comprising the second magnetoelectric material;
a fifth structure comprising the second magnet, wherein the fifth structure is adjacent to the fourth structure; and
a sixth structure comprising the second spin orbit material, wherein the sixth structure is adjacent to the fifth structure, wherein the fifth structure is between the fourth structure and sixth structure.

4. The apparatus of claim 3, wherein the third or sixth structures include one or more of: β-Ta, β-W, W, Pt, Cu doped with Iridium, Cu doped with Bismuth, or Cu doped an element of 3d, 4d, 5d, 4f, or 5f of periodic table groups.

5. The apparatus of claim 3, wherein the first or fourth structures include BFO, SRO, and STO.

6. The apparatus of claim 3 comprises:
a first transistor controllable by a first phase of a clock, wherein the first transistor is coupled to the third structure; and
a second transistor controllable by a second phase of the clock, wherein the second transistor is coupled to sixth structure, wherein the first phase and second phase are different and do not overlap.

7. The apparatus of claim 3, wherein the first magnet is a first ferromagnet, and wherein the second structure comprises:
a second ferroelectric magnet; and
an insulative ferroelectric magnet between the first ferroelectric magnet and the second ferroelectric magnet.

8. The apparatus of claim 1, wherein the first or second magnetoelectric material include one or more of: BiFeO₃, LuFeO₂, LuFe₂O₄, or La doped BiFeO₃, or wherein the multiferroic material includes one of: Bi, Fe, O, Lu, or La.

9. The apparatus of claim 1, wherein the first or second magnets include a paramagnet or a ferromagnet, or wherein the first and second magnets comprises a material which includes one or more of: Pt, Pd, W, Ce, Al, Li, Mg, Na, Cr, O, Co, Dy, Er, Eu, Gd, Fe, Nd, K, Pr, Sm, Tb, Tm, or V.

10. The apparatus of claim 1, wherein the first or second magnets include one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, Ru.

11. An apparatus comprising:
a first differential cell comprising a first magnetoelectric material, a first spin orbit material, and a first magnet, coupled together; and
a second differential cell comprising a second magnetoelectric material, a second spin orbit material, and a second magnet coupled together, wherein the first spin orbit material is coupled to a first terminal of the second magnetoelectric material and a second terminal of the second magnetoelectric material.

12. The apparatus of claim 11, wherein the first or second magnets include a paramagnet or a ferromagnet, or wherein the first and second magnets comprises a material which includes one or more of: Pt, Pd, W, Ce, Al, Li, Mg, Na, Cr, O, Co, Dy, Er, Eu, Gd, Fe, Nd, K, Pr, Sm, Tb, Tm, or V.

13. The apparatus of claim 11, wherein the first or second magnets include one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, or Ru.

14. The apparatus of claim 11 comprises:
a first transistor controllable by a first phase of a clock, wherein the first transistor is coupled to the first spin orbit material; and
a second transistor controllable by a second phase of the clock, wherein the second transistor is coupled to the second material, wherein the first phase and second phase are different and do not overlap.

15. The apparatus of claim 11, wherein the first or second magnetoelectric material include one or more of: BiFeO₃, LuFeO₂, LuFe₂O₄, or La doped BiFeO₃, or wherein the multiferroic material includes one of: Bi, Fe, O, Lu, or La.

16. A system comprising:
a memory;
a processor coupled to the memory; and
a wireless interface to allow the processor to communicate with another device, wherein the processor includes:
a first differential cell comprising a first magnetoelectric material, a first spin orbit material, and a first magnet, coupled together; and
a second differential cell comprising a second magnetoelectric material, a second spin orbit material, and a second magnet coupled together, wherein the first spin orbit material is coupled to a first terminal of the second magnetoelectric material and a second terminal of the second magnetoelectric material.

17. The system of claim 16, wherein the first or second magnets include a paramagnet or a ferromagnet, or wherein the first and second magnets comprises a material which includes one or more of: Pt, Pd, W, Ce, Al, Li, Mg, Na, Cr, O, Co, Dy, Er, Eu, Gd, Fe, Nd, K, Pr, Sm, Tb, Tm, or V.

18. The system of claim 16, wherein the first or second magnets include one or a combination of materials which includes one or more of: a Heusler alloy, Co, Fe, Ni, Gd, B, Ge, Ga, permalloy, or Yttrium Iron Garnet (YIG), and wherein the Heusler alloy is a material which includes one or more of: Cu, Mn, Al, In, Sn, Ni, Sb, Ga, Co, Fe, Si, Pd, Sb, V, or Ru.

19. The system of claim 16, wherein the processor comprises:
a first transistor controllable by a first phase of a clock, wherein the first transistor is coupled to the first spin orbit material; and
a second transistor controllable by a second phase of the clock, wherein the second transistor is coupled to the second material, wherein the first phase and second phase are different and do not overlap.

20. The system of claim 16, wherein the first or second magnetoelectric material include one or more of: BiFeO₃, LuFeO₂, LuFe₂O₄, or La doped BiFeO₃, or wherein the multiferroic material includes one of: Bi, Fe, O, Lu, or La.
